(19) United States
(12) Patent Application Publication
(10) Pub. No.: US 2008/0144299 A1
(43) Pub. Date: Jun. 19, 2008

(54) Systems for and methods of circuit construction

(76) Inventor: Frank E. Redmond, Issaquah, WA (US)

Correspondence Address: FRANK E. REDMOND III, 92 Sky Ridge Road NW, Issaquah, WA, 98027, US

(21) Appl. No.: 11/998,229

(22) Filed: Nov. 29, 2007

Related U.S. Application Data
(63) Continuation-in-part of application No. 10/892,880, filed on Jul. 15, 2004.

(51) Int. Cl. H05K 1/18; H05K 7/12

(52) U.S. Cl. 361/764; 361/771

(57) ABSTRACT

A printed circuit board having only one circuit element, said circuit element having one or more leads and each lead being in electrical communication to one end of a trace on the printed circuit board, wherein said trace has a second end terminating at a pad, wherein said pad is in electrical communication with a receptacle capable of receiving and retaining a wire. A printed circuit board selected from the group consisting of a printed circuit board having only two traces, a printed circuit board having only three traces, a printed circuit board having only four traces, a printed circuit board having only six traces, a printed circuit board having only eight traces, a printed circuit board having only ten traces, a printed circuit board having only twelve traces, a printed circuit board having only fourteen traces and a printed circuit board having only sixteen traces, wherein each trace has two ends, one end being a receptacle pad connected to a receptacle capable of receiving and retaining a wire, and the second end of said trace being a lead-pad electrically connected to a lead-receptacle, wherein said lead-receptacle is capable of receiving and retaining a lead or pin from a circuit element.

This is a continuation-in-part of U.S. patent application Ser. No. 10/892,880 filed on Jul. 15, 2004, the entire contents of which are incorporated herein by reference.

### BACKGROUND

In the field of electronics, it is often desirable to construct a working model of an electronic circuit, a circuit being multiple electronic elements interconnected in one (or more) closed signal routes to perform a desired electronic or electrical function. A working model of an electronic circuit may serve a number of purposes, such as, for example, a preliminary pattern serving as the plan from which a circuit not yet constructed will be produced, or a tentative description of a theoretical circuit that accounts for all of the known properties of the circuit.

Existing circuit modeling systems (such as those associated with, for example, breadboards, wire-wrap boards, etc.) typically involve mounting multiple electronic elements and/or prepackaged integrated circuits (themselves consisting of multiple electronic elements) to a single shared surface (e.g. board) using a single interconnection that is both electronic (i.e. electrically conductive) and mechanical.

Among the problems associated with interconnecting packaged electronic elements and circuits to a single shared surface is the fact that the resulting surface (e.g. board) is preformed (i.e., its size and shape are predefined) and difficult to alter. As such, these circuits do not readily lend themselves to element-by-element reconfiguration, which is often required when designing and/or experimenting with circuits for particular purposes.

Thus, there is a need for developing a new method & apparatus for more easily constructing and designing electronic circuits.

### DESCRIPTION

The present invention fills this need by providing for a printed circuit board having only one circuit element, said circuit element having one or more leads and each lead being in electronic communication to a lead-pad at one end of a trace on the printed circuit board, wherein said trace has a second end terminating at a wire-pad capable of connecting to a wire. Preferably, the wire-pad is in electronic communication and connected to a receptacle capable of receiving and retaining a wire.

The present invention further provides for a printed circuit board having a pre-determined, specific number of traces. Included among these are a printed circuit board having only two traces, a printed circuit board having only three traces, a printed circuit board having only four traces, a printed circuit board having only six traces, a printed circuit board having only eight traces, a printed circuit board having only ten traces, a printed circuit board having only twelve traces, a printed circuit board having only fourteen traces and a printed circuit board having only sixteen traces, wherein each trace has two ends, one end being a wire-pad that can connect to a wire, and the second end of said trace being a lead-pad to be connected to a lead from an electronic element. Also included are printed circuit boards that only have 18-64 traces but no more. In alternative embodiments of the above-described printed circuit boards the wire-pad of each trace is connected to a wire-receptacle capable of receiving and retaining a wire. In other embodiments of the above-described printed circuit boards, the lead-pad of each trace is connected to a lead-receptacle capable of receiving and retaining a lead of a circuit element.

The above-described printed circuit boards preferably have at least four sides, wherein two sides of each printed circuit board have lengths ranging from about 0.25 inches to about 7 inches. Preferably two sides of each printed circuit board each have a length selected from the group consisting of 0.4 inches, 1.1 inches, 1.8 inches, 2.5 inches, 3.2 inches, 3.9 inches and 4.9 inches.

The present invention further provides for a printed circuit board wherein said printed circuit board has the same number of traces as the circuit element attached to the printed circuit board has leads, and wherein each trace is in electronic communication with a wire-pad capable of connecting to a wire and preferably the wire-pad is connected to a wire-receptacle capable of receiving and retaining a wire. Such wire-receptacles can be obtained from the Mill-Max Mfg. Co., Oyster Bay, N.Y.

Each of the above-described printed circuit boards has one to three circuit elements attached to the circuit board. Preferably, each printed circuit board has only one circuit element. Examples of circuit elements that can be attached to each circuit board are 2-lead electronic elements such as resistors, diodes, a light emitting diodes (LEDs), capacitors, single pole single throw (SPST) switches, push-button (PB) switches, speakers, microphones, crystals, lamps, meters, battery-holders, photoresistors, photodiodes, phototransistors and solar cells; 3-lead electronic elements such transistors, variable resistors, silicon controlled rectifiers, single Pole Double Throw (SPDT) switches; linear integrated circuits such as amplifiers, operational amplifiers, comparators, inverters, counters, timers, function generators such as sound generators, and voltage regulators; digital integrated circuits such as logic gates, buffers, inverters, selectors/distributors, encoders/decoders, multiplexers/demultiplexers, counters and timers.

The present invention is directed to a process and apparatus for designing and building a working model of a complex electronic circuit. The process is comprised of using multiple electronic elements wherein each electronic element is on its own separate printed circuit board. Each electronic element has one or more leads, and each lead is connected to a lead-pad at the end of a trace and each trace has a second end terminating at a wire-pad capable of connecting to a wire. Thus, a lead of a circuit element on one circuit board is connected to a lead of a circuit element on a second circuit board by connecting one end of a wire to a wire-pad at the end of a trace on a first circuit board and the other end of the wire with a wire-pad at the end of a trace on the second circuit board. This process is repeated until all the required element leads are interconnected to create a working circuit. In preferred embodiments each wire-pad has a receptacle therein that is adapted to receive and retain the end of a wire. In this way, a model of a complex electronic circuit can be made. Using the process of the present invention a model of an electronic circuit can easily be assembled, in which an initial electronic element can easily be removed and replaced with another one when it became apparent that the first electronic element was not appropriate.

A circuit is created, according to the process of the present invention, by connecting one end of a wire to a wire-pad on one printed circuit board and connecting the other end of the wire to a wire-pad on another printed-circuit board. Each wire-pad is connected to a trace, which is connected to a lead of a circuit element. This connects and brings into electrical communication one lead of one circuit element on one printed circuit board with one lead of another circuit element on a different printed circuit board. This process is repeated until all the required element leads are interconnected to create a working circuit. The wire used to connect one circuit board to another preferably has a diameter of 101.9 mm (10 gauge), 80.8 mm (12 gauge), 64.1 mm (14 gauge), 50.8 mm (16 gauge), 40.3 mm (18 gauge), 32.0 mm (20 gauge), 25.4 mm (22 gauge), 20.1 mm (24 gauge), 15.9 mm (26 gauge), 12.6 mm (28 gauge), 10.0 mm (30 gauge), 7.9 mm (32 gauge), 6.3 mm (34 gauge), 5.0 mm (36 gauge), 4.0 mm (38 gauge) and 3.1 mm (40 gauge). The wire-receptacles will have a size corresponding to the size or gauge of wire used.

### BRIEF DESCRIPTION OF THE DRAWINGS

FIG. 1 is an exploded isometric perspective view of a circuit portion according to an embodiment of the invention.

FIG. 2 is an exploded isometric perspective view of the circuit board portion 20 of the circuit portion 10 illustrated in FIG. 1.

FIG. 3 is an exploded isometric perspective view of a circuit according to an embodiment of the invention; and

FIG. 4 is an isometric perspective view of the circuit of FIG. 3 in an assembled state.

FIG. 5 is an isometric view of a printed circuit board having only two traces.

FIG. 6 is an exploded isometric view of a printed circuit board of FIG. 5.

FIG. 7 is an isometric view of a printed circuit board portion of FIG. 5 with a resistor attached to said printed circuit board.

FIG. 8 is an isometric view of a printed circuit board with element lead receptacles that allow a lead of an electronic circuit element to be temporarily attached to the printed circuit board.

FIG. 9 is an exploded isometric view of a circuit board portion with element lead receptacles that allow a lead of an electronic element to be temporarily attached to the printed circuit board.

FIG. 10 is an isometric view of a printed circuit board with a resistor temporarily attached.

FIG. 11 is an exploded isometric view of a printed circuit board having an LED that is to be attached to the printed circuit board.

FIG. 12 is an isometric view of a printed circuit board of FIG. 11 with an LED attached to the printed circuit board.

FIG. 13 is an exploded isometric view of a printed circuit board with square posts that are to be attached to the printed circuit board.

FIG. 14 is an isometric view of the printed circuit board of FIG. 13 with the square posts attached to the printed circuit board.

FIG. 15 has three printed circuit boards, each printed circuit board having a different electronic element.

FIG. 16 is an isometric view of a wire conductor with bare ends.

FIG. 17 is an isometric view of a circuit created from three printed circuit boards, each printed circuit board having a different electronic element and three wire conductors connecting the three printed circuit boards to form a complete circuit.

FIG. 18 shows a capacitor attached to a printed circuit board.

FIG. 19 shows a printed circuit board having an SPST switch connected to the printed circuit board.

FIG. 20 shows a printed circuit board having a PB switch connected to the printed circuit board.

FIG. 21 shows a printed circuit board having a speaker connected onto the printed circuit board.

FIG. 22 shows a printed circuit board having a microphone connected onto the printed circuit board.

FIG. 23 shows a crystal attached to a printed circuit board.

FIG. 24 shows a printed circuit board having a lamp connected onto the printed circuit board.

FIG. 25 shows a meter attached to a printed circuit board.

FIG. 26 shows a printed circuit having a power-supply, in this case a battery-holder, attached to the printed circuit board.

FIG. 27 shows such a printed circuit board having three traces.

FIG. 28 shows transistor having three leads that is to be attached to a printed circuit board having three traces.

FIG. 29 shows the transistor attached to a printed circuit board of FIG. 28.

FIG. 30 shows a variable resistor having three leads attached to a printed circuit board having three traces.

FIG. 31 shows a silicon-controlled rectifier that has three leads attached to a printed circuit board that has three traces.

FIG. 32 shows an SPDT switch that has three leads attached to a printed circuit board that has three traces.

FIG. 33 shows a printed circuit board having four traces onto which an integrated circuit having four pins or leads can be attached.

FIG. 34 shows an integrated chip, which is a 4 dual in-line chip that is to be attached to a printed circuit board.

FIG. 35 shows a 4 dual in-line integrated chip attached to a printed circuit board that has only four traces.

FIG. 36 shows a printed circuit board having only six traces onto which an integrated circuit having six pins or leads can be attached.

FIG. 37 shows a six-pin integrated chip that is to be inserted onto a printed circuit board of FIG. 36 having six traces.

FIG. 38 shows a six-pin integrated chip of FIG. 37 attached to a printed circuit board having six traces.

FIG. 39 shows a printed circuit board having eight traces onto which an integrated circuit having eight pins or leads can be attached.

FIG. 40 shows an eight-pin integrated chip that is to be inserted onto a printed circuit board of FIG. 39 that has eight traces.

FIG. 41 shows an eight-pin integrated chip attached to a printed circuit board of FIG. 39 that has eight traces.

FIG. 42 shows a printed circuit board that has ten traces onto which an integrated circuit having 10 pins or leads can be attached.

FIG. 43 shows a ten-pin integrated chip that is to be inserted onto printed circuit board of FIG. 42 that has ten traces.

FIG. 44 shows a ten-pin integrated chip that is inserted onto a printed circuit board of FIG. 42 that has ten traces.

FIG. 45 shows a printed circuit board having fourteen traces onto which an integrated circuit having fourteen pins or leads can be attached.

FIG. 46 shows a fourteen-pin integrated chip that is to be inserted onto the printed circuit board of FIG. 45 that has fourteen traces.

FIG. 47 shows a fourteen-pin integrated chip that is inserted onto printed circuit board of FIG. 45 that has fourteen traces.

FIG. 48 shows a printed circuit board having sixteen traces onto which a chip having sixteen leads or pins can be attached.

FIG. 49 shows a sixteen-pin integrated chip that is to be inserted onto the printed circuit board of FIG. 48 that has sixteen traces.

FIG. 50 shows a sixteen-pin integrated chip attached to the printed circuit of FIG. 48 that has sixteen traces.

The present invention will now be described more fully hereinafter with reference to the accompanying drawings, in which preferred embodiments of the invention are shown. This invention may, however, be embodied in different forms and should not be construed as limited to the embodiments set forth herein. Rather, these embodiments are provided so that this disclosure will be thorough and complete, and will fully convey the scope of the invention to those skilled in the art. Like reference numbers signify like elements throughout the description of the figures.

### DEFINITIONS

A printed circuit board is comprised of a flat panel of insulating base material with a pattern drawn in copper foil on one or more sides. The copper pattern on a printed circuit board is made up primarily of two shapes: pads (or lands) and traces (or tracks).

A printed circuit is a circuit in which the interconnecting wires have been replaced by conductive strips printed or etched onto an insulating board.

Pads provide a surface for mounting electronic element leads (or terminations). Pads can be round, rectangular, oval or other shapes. Some pads have a plated-thru hole (PTH), a hole with conductive plating on its walls, in their center for accepting element leads. Other pads do not have plated-thru holes; instead the element leads rest on top of the pad.

Traces are conductors that interconnect pads.

When electronic element leads are connected to their pads, the traces connect the leads and create a working circuit.

The printed circuit board base material acts as a support and backing material for the copper pattern. It also acts as an electrical insulator to isolate individual pads and traces from each other.

The set of interconnecting pads and traces is often referred to as the printed circuit board artwork. The name printed circuit board suggests that printing processes are involved in drawing the artwork on the board. And printing processes are often used to transfer an image to a printed circuit board. But the actual copper image is usually created NOT by printing, but by chemically etching away unwanted copper from a copper-coated surface. Other terms that are sometimes used to describe PCBs include printed wiring boards and etched wiring boards.

The present invention is directed to a process and apparatus for designing and building a working model of an electronic circuit. The process is comprised of using multiple electronic elements wherein each electronic element is mounted on its own separate printed circuit board with each electronic element lead being electrically connected (e.g. using pads and traces) to an individual receptacle (generally female in nature) that is adapted to receive and retain the end of an electrically conductive wire (which is male in nature). The leads of an electronic element on one printed circuit board can be electrically connected to the leads of an electronic element on another printed circuit board by means of an electrically conductive wire. Each end of the wire (which is generally male in nature), is inserted into a receptacle (which is generally female in nature) that is electrically connected (e.g. using pads and traces) to an electronic element lead on one printed circuit board, the wire then extending and connecting into a second receptacle that is electrically connected (e.g. using pads and traces) to a second electronic element lead on a second printed circuit board. In preferred embodiments each electronic element lead is electrically connected (e.g. using pads and traces) to a female receptacle that is adapted to receive and retain the end of a wire (which is male in nature). In this way, a working model of an electronic circuit can be made.

In the past, building a working model of an electronic circuit, involved mounting electronic elements to one large printed circuit board with a preformed shape and size. Attaching electronic elements to one large printed circuit board with a preformed shape and size, makes it very difficult to change the shape or size of the board or to change the electronic elements mounted to the board. Using the process and apparatus of the present invention a working model of an electronic or electric circuit can easily be assembled, in which the shape and size of the final assembled circuit board, as well as the electronic elements of the circuit can be easily changed.

Prior art methods also exist that involve mounting (surface mount) electronic elements to separate printed circuit boards with each element lead being electrically connected (e.g. using pads and traces) to an individual male pin. These methods require female receptacles to be added to the ends of any wire conductor, before the conductor can be used to electrically connect the two male pins that are connected to the element leads. However, by electrically connecting each element lead to an individual female receptacle, the present invention allows any two female receptacles that are connected to the element leads to be electrically interconnected using a single-piece of wire conductor.

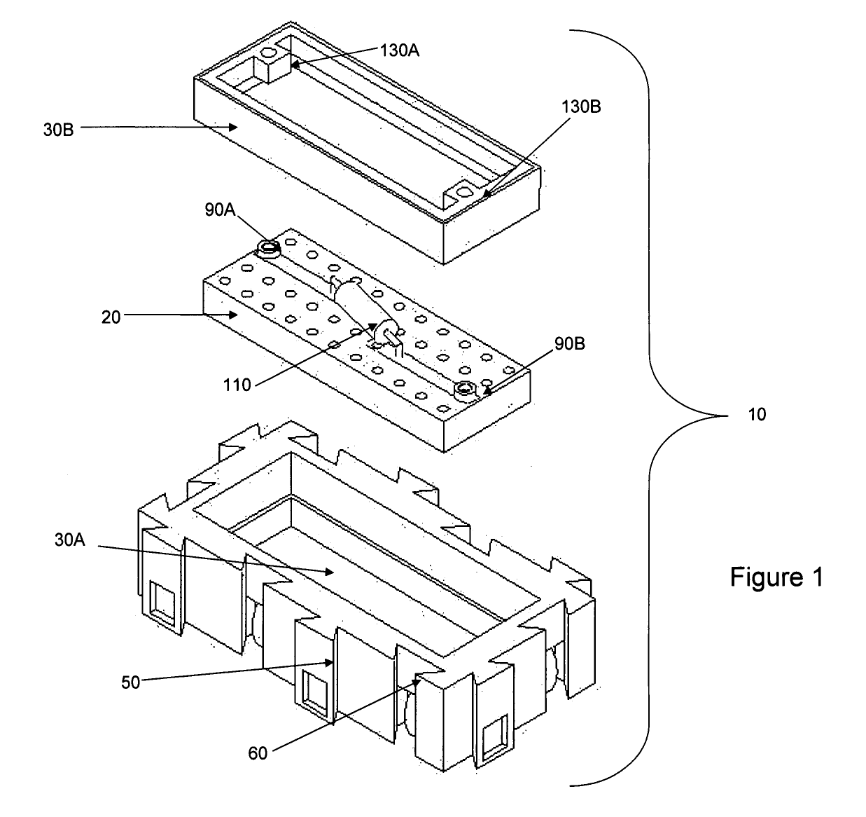

FIG. 1 is an exploded isometric perspective view of a circuit portion 10 according to an embodiment of the invention. The circuit portion 10 includes a printed circuit board portion 20 that may be enclosed, when the circuit portion 10 is fully assembled, within a body portion 30 that includes a bottom portion 30A and a top portion 30B. As is illustrated in FIG. 1, the bottom portion 30A of the body portion 30 includes, in an embodiment, a series of male connectors 50 and female connectors 60 around the perimeter of the bottom portion 30A of the body portion 30. As discussed in further detail below, the male connectors 50 and female connectors 60 enable attachment of the circuit portion 10 to a similarly configured circuit portion.

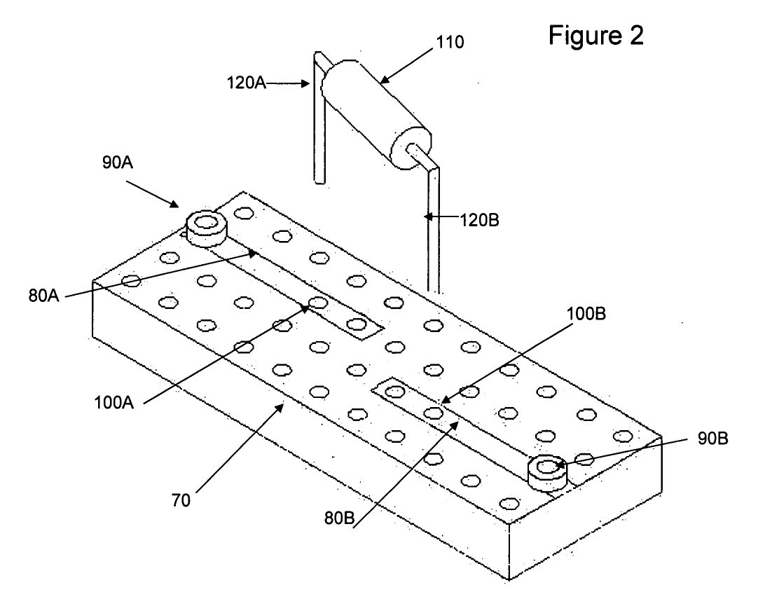

FIG. 2 is an exploded isometric perspective view of the printed circuit board 20 of the circuit portion 10 illustrated in FIG. 1. The circuit board portion 20 includes a printed circuit board 70 that, in an embodiment, consists of an insulating material, such as epoxy, resin or other material, known in the art, suitable for construction of a circuit board. In an embodiment, the printed circuit board 70 includes multiple board traces 80A, 80B consisting of a conductive material, such as copper foil or other suitable conductive material. Although the board 70 illustrated in FIG. 2 includes only two leads, the board may have, in varying embodiments, more or fewer than two leads.

As illustrated in FIG. 2, each trace 80A, 80B includes wire-receptacles 90A, 90B, which may be elevated above a surface of the circuit board 70, and lead pads 100A, 100B. In the illustrated embodiment, the terminals 90A, 90B, 100A, 100B comprise a recess or hole in a surface of the circuit board 70. It should be noted, however, that the terminals 90A, 90B, 100A, 100B need not comprise a recess or hole, but may instead comprise any other connective terminal configuration known in the art.

The circuit board portion 20 may further include a circuit element 110. The circuit element 110 may be a resistor, capacitor, cell, diode, or any other well-known element used to construct an electronic circuit. In an embodiment, the circuit element 110 includes element leads 120A, 120B operable to be received by respective terminals 100A, 100B. When the lead pads 100A, 100B receive the element leads 120A, 120B, the circuit board traces 80A, 80B and, consequently, the wire-receptacles 90A and 90B are electrically coupled to the circuit element 110.

As is shown in FIG. 1 and FIG. 2, the top 30B of the body portion 30 includes body portion holes 130A, 130B. When the board portion 20 is situated within the body portion 30, the body portion holes 130A, 130B are coaxial with respective terminals 90A, 90B. Accordingly, and as further discussed below, an object external to the portion 10 may be brought into contact with a terminal 90A, 90B by inserting such object into a corresponding body portion hole 130A, 130B.

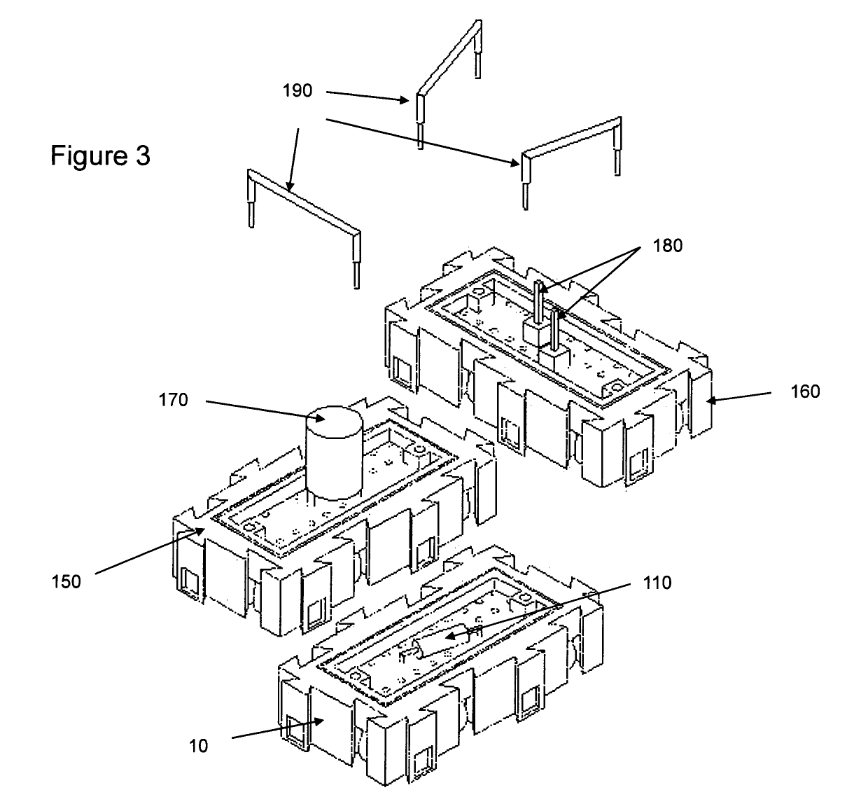

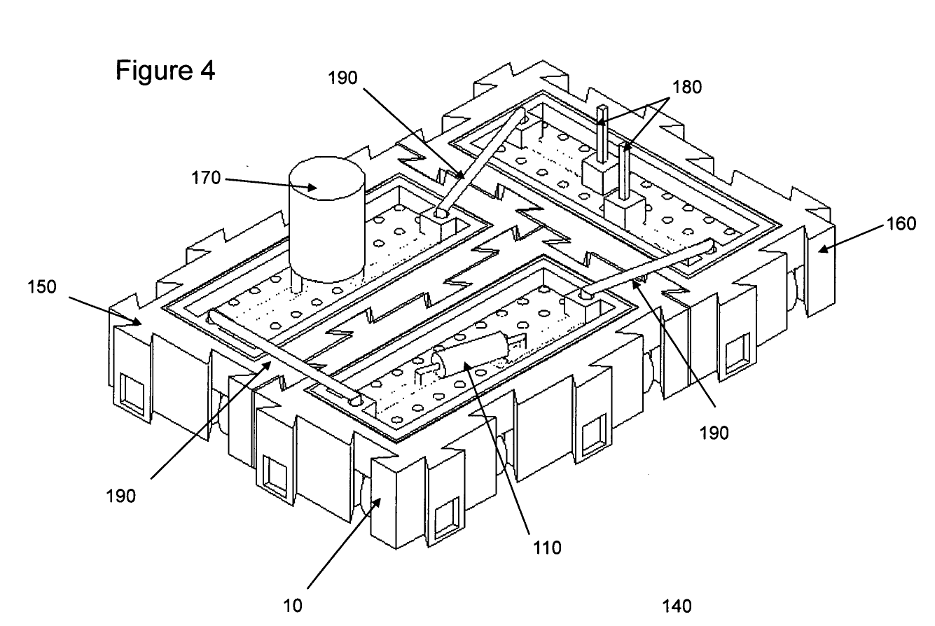

FIG. 3 illustrates an exploded isometric perspective view of a circuit 140, an assembled embodiment of which is illustrated in FIG. 4. In the illustrated embodiment, the circuit 140 consists of three circuit portions 10, 150, 160. The circuit portions 150, 160 have a general configuration identical to that of the circuit portion 10 described above in detail. As can be seen in both FIGS. 3 and 4, each circuit portion 150, 160 includes a respective circuit element 170, 180 that may be, but is not necessarily, different in function from the circuit element 110 of the circuit portion 10.

An important feature of an embodiment of the invention is that the circuit portions 10, 150, 160 can be physically attached to one another without there existing an electrical coupling between or among such physically attached circuit portions 10, 150, 160. In constructing the circuit 140, the circuit portions 10, 150, 160 may be attached to one another, as best shown in FIG. 4, by their respective corresponding male and female connectors 50, 60. It should be understood that, while male/female connectors are employed in the illustrated embodiments, the printed circuit boards 10, 150, 160 may be attached or otherwise connected physically to one another in a number of ways known in the art. These physical connections may be removable (i.e., non-permanent) such that the portions 10, 150, 160 may be easily coupled to and decoupled from one another.

Once the circuit portions 10, 150, 160 are physically attached to one another, electrically conductive lead pins 190 may be inserted into corresponding body portion holes (such as the holes 130A and 130B associated with portion 10) of the circuit portions 10, 150, 160. The conductive pins 190, once inserted into the body portion holes, electrically contact a corresponding one of the wire-receptacles (such as the wire-receptacles 90A and 90B associated with portion 10) of the circuit portions 10, 150, 160. As a result, the circuit elements 110, 170, 180 can be electrically coupled to one another via the lead pins 190. For example, by inserting one end of a pin 190 into a body portion hole of the portion 150 and by inserting the other end of the same pin 190 into a body portion hole of the portion 10, the circuit elements 170 and 110 are electrically coupled to each other.

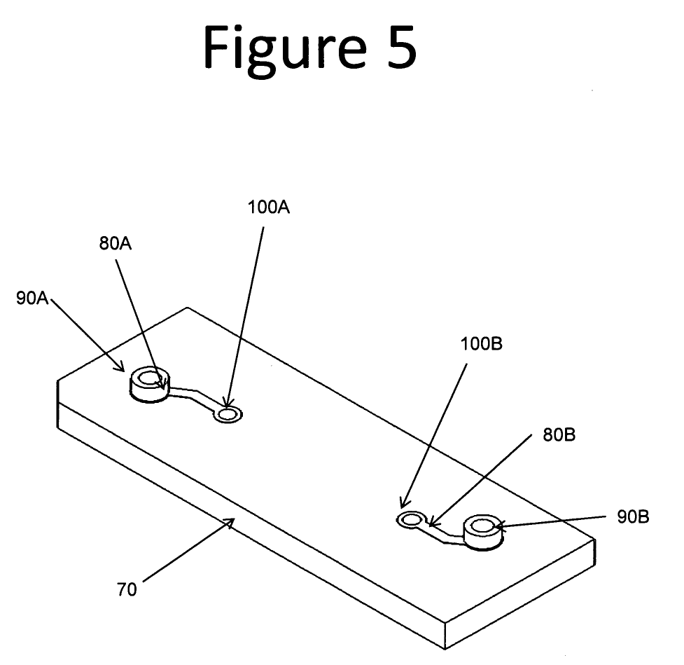

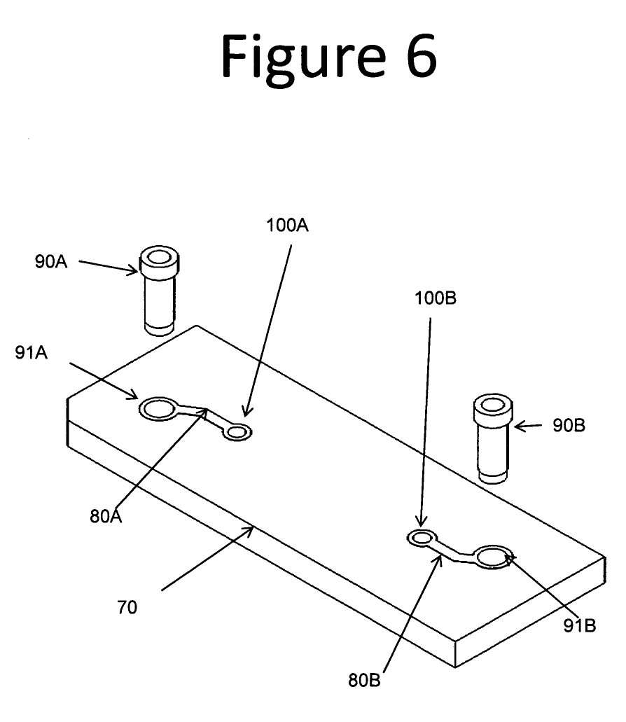

FIG. 5 shows a claimed printed circuit board, 70 having only two traces, 80A and 80B. Trace 80A extends from lead pad 100A to wire-receptacle 90A. As can be seen in FIG. 6, wire-receptacle 90 A is inserted in printed circuit board 70 so as to be in electrical communication with receptacle pad 91A, which lies at an end of trace 80A opposite lead pad 100A. Trace 80B extends from lead pad 100B to wire-receptacle 90B. As can be seen in FIG. 6, wire-receptacle 90B is inserted in printed circuit board 70 so as to be in electrical communication with receptacle pad 91B, which lies at an end of trace 80B opposite lead pad 100B.

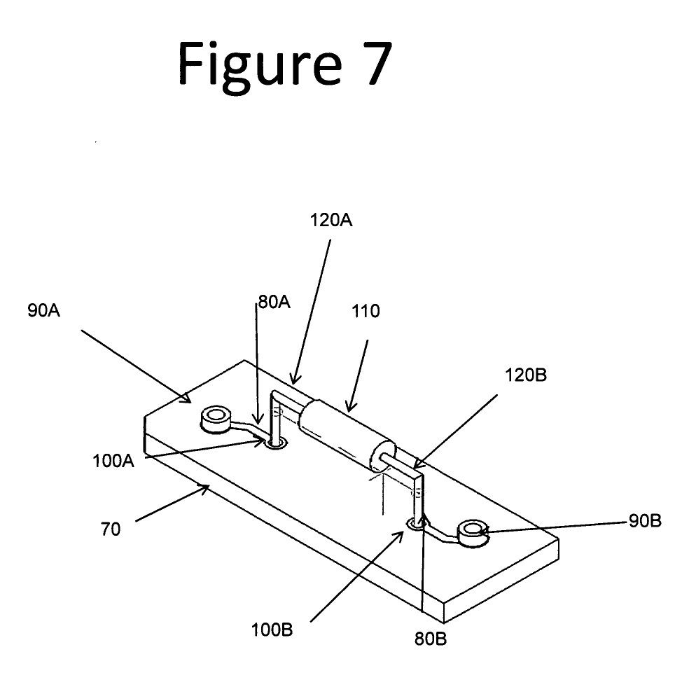

FIG. 7 shows a electronic element 110 having two leads, 120A and 120B attached to printed circuit board 70. Lead 120A is attached to and is in electrical communication with lead-pad 100A, which is at one end of trace 80A which terminates and is in electrical communication with wire-receptacle 90A. Lead 120B of electronic element 110 is attached to and is in electrical communication with lead-pad 100B, which is at one end of trace 80B, which terminates and is in electrical communication with wire-receptacle 90B. Generally leads 120A and 120B are permanently attached to their respective lead-pads 100A and 100B by means of solder. However, they need not be so attached and may be removable allowing electronic elements to be changed at will.

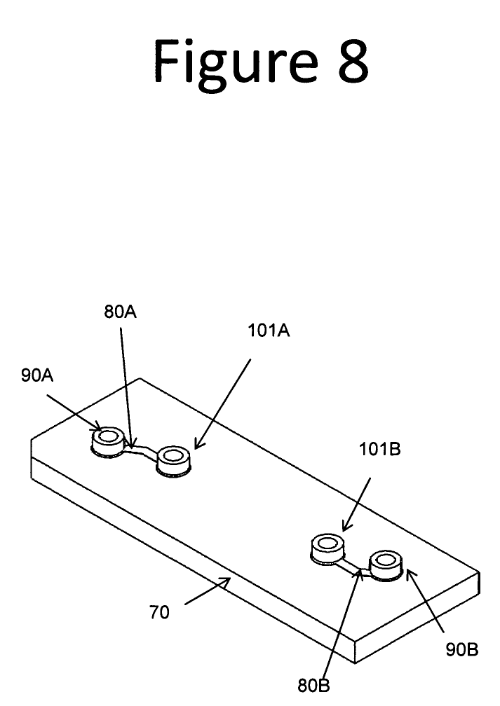

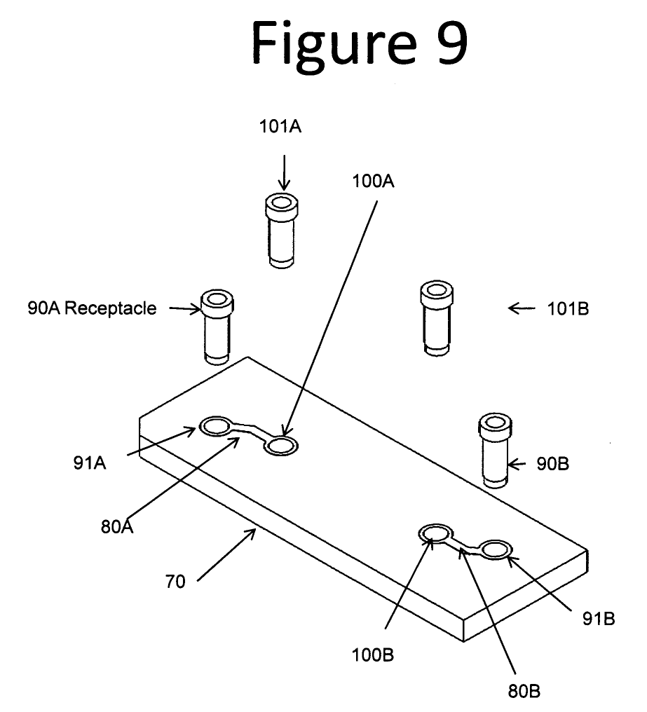

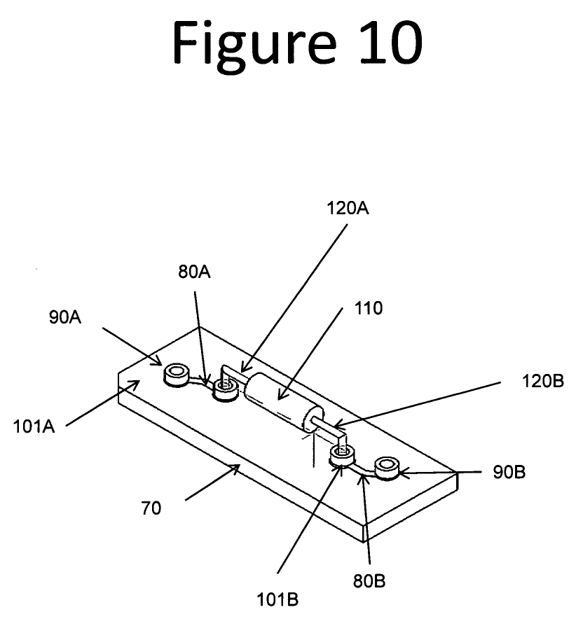

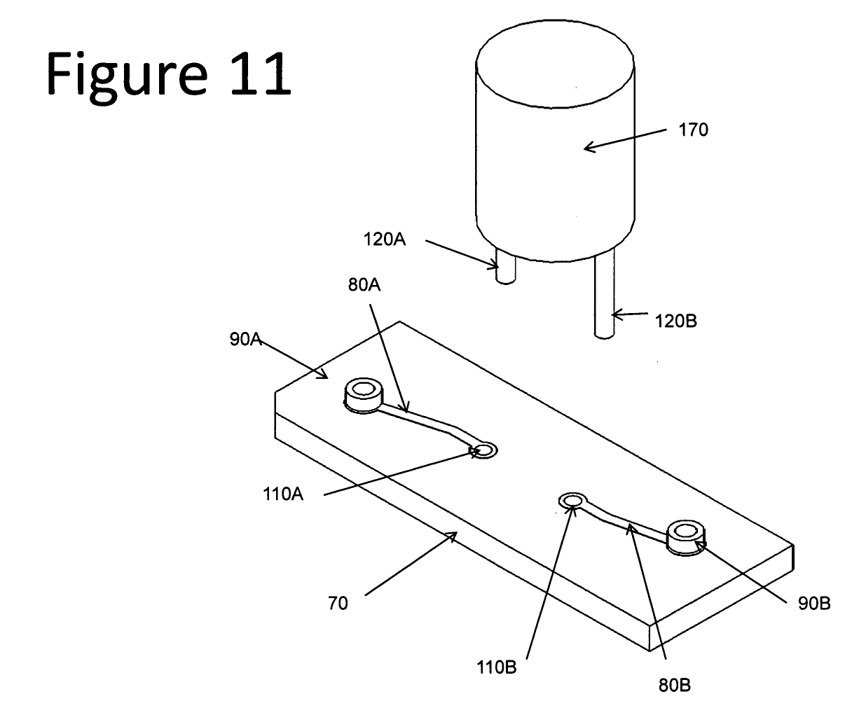

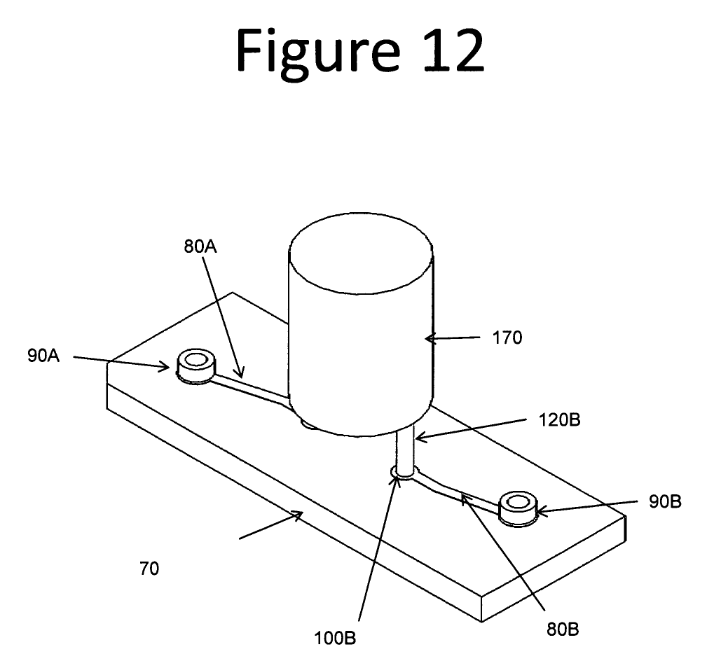

FIGS. 8 and 9 show alternative printed circuit boards showing lead-receptacle 101A inserted into printed circuit board 70 so that lead-receptacle 101A is attached to and is in electrical communication with lead-pad 100A. Lead-receptacle 101B is inserted into lead-pad 100B, which is attached to and in electrical communication with trace 80B. By having a lead-receptacle attached to each of the lead-pads, a two-lead element can be easily removed and exchanged for a different two-lead element. FIG. 10 shows an example of this in which an electronic element 110 is attached to printed circuit board 70, in which lead 120A of electronic element 110 is inserted into lead-receptacle 101A, resulting in lead 120A being in electrical communication with trace 80A and wire-receptacle 90A. Also lead 120B of element 110 is inserted into lead-receptacle 101B, resulting in lead 120B being in electrical communication with trace 80B and wire-receptacle 90B. Thus, element 110, in this case a resistor, can easily be removed and replaced with another resistor in case the resistor is burnt out or it is determined that a different resistor is needed that has a higher or lower value. Also the resistor can be replaced with an entirely different two-lead element such as a light-emitting-diode (LED) 170 as is shown in FIGS. 11 and 12.

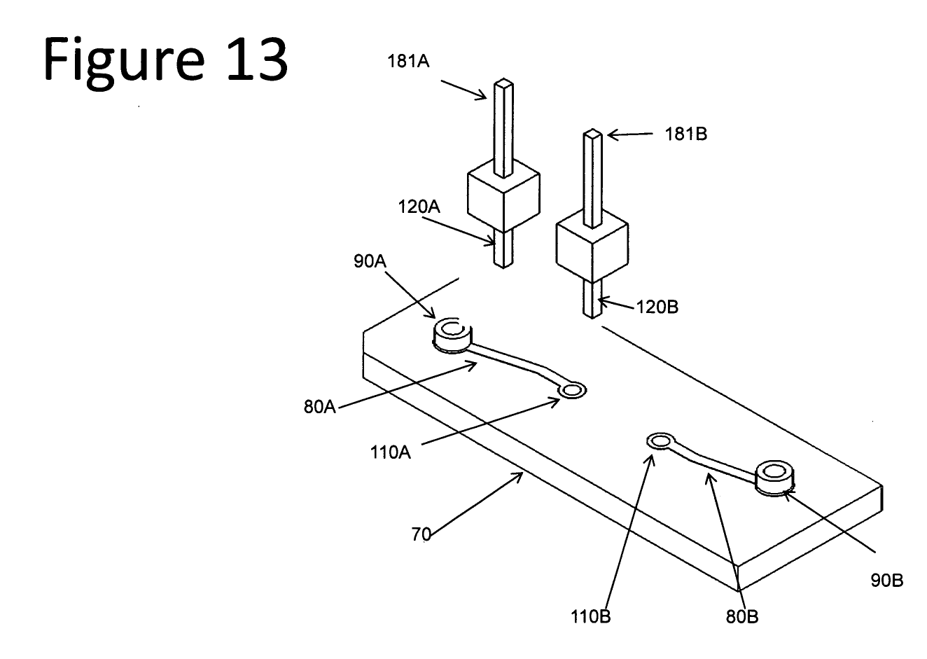

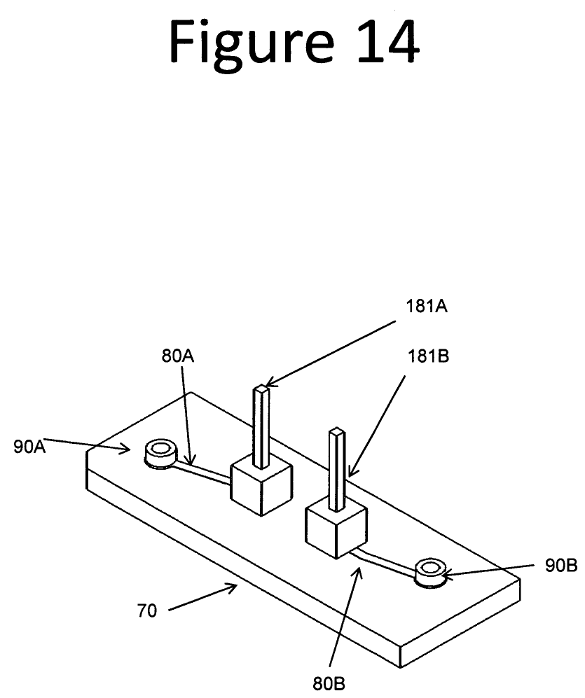

FIGS. 13 and 14 show printed circuit board 70 in which the two-lead electronic element 180 is a pair of posts 181A and 181B onto which a number of elements to can be plugged. Examples of such electronic elements that can be plugged into such posts include, a battery-holder, a solar-cell, and a motor by way of example. Lead 120A will be inserted into printed circuit board 70 so that the lead is in electrical communication with lead-pad 100A, and lead 120B is inserted into printed circuit board 70 so that lead 120B is in electrical communication with lead-pad 100B. Thus lead 120A and thus post 181A are in electrical communication with trace 80A and wire-receptacle 90A. Also lead 120B and thus post 181B are in electrical communication with trace 80B and wire-receptacle 90B.

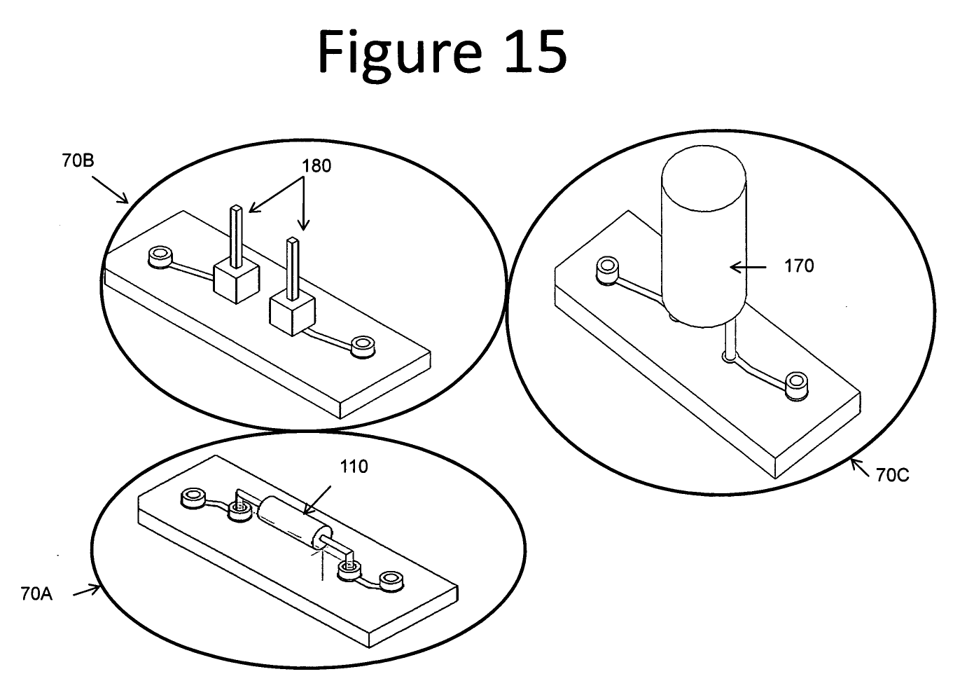

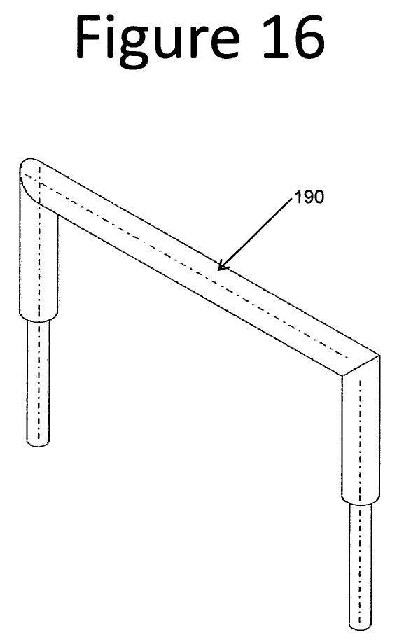

FIG. 15 shows three separate printed circuit boards, 70A, 70B, and 70C of the present invention each having one two-lead electronic element attached to the respective printed circuit boards. FIG. 16 shows a wire 190 the ends of which can fit into a wire-receptacle 90 of a printed circuit board 70.

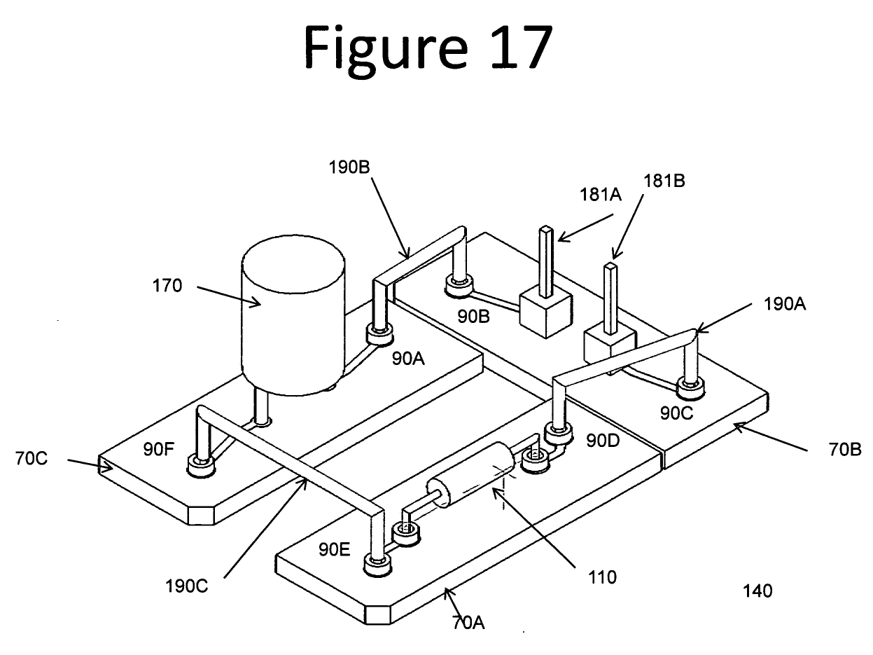

FIG. 17 shows a simple electronic circuit 140 comprised of printed circuit boards 70A, 70B and 70C. One end of a wire 190A is inserted into wire-receptacle 90D of circuit board 70A and the opposite end of wire 190A is inserted into wire-receptacle 90C of circuit board 70B. This puts one lead of electronic element 110 on circuit board 70A in electrical communication with the lead of electronic element 181B on circuit board 70B. One end of a wire 190B is inserted into wire-receptacle 90B of circuit board 70B and the opposite end of wire 190B is inserted into wire-receptacle 90A of circuit board 70C. This puts one lead of electronic element 170 on circuit board 70C in electrical communication with one lead of electronic element 181A on circuit board 70B. One end of a wire 190C is inserted into wire-receptacle 90F of printed circuit board 70C and the opposite end of wire 190C is inserted into wire-receptacle 90E of printed circuit board 70A. This puts one lead of electronic element 110 on printed circuit board 70A in electrical communication with one lead of electronic element 170 on circuit board 70C, and completes the circuit 140 in which the leads of the three electronic elements 110, 170, and 181 A&B are in electrical communication with each other.

The electronic elements used on the printed circuit boards of the present invention can be classified as discrete electronic elements or integrated circuit (IC) elements. Discreet elements are generally individual elements, meaning they have one function, and generally have 1 to three leads. An example of a one-lead element is an antenna. Examples of 2-lead elements are, resistors, diodes, LEDs, capacitors, single-pole single-throw (SPST) switches, push-button (PB) switches, speakers, microphones, crystals, lamps, meters, battery holders, photoresistors, photodiodes, phototransistors, and solar cells to name just a few.

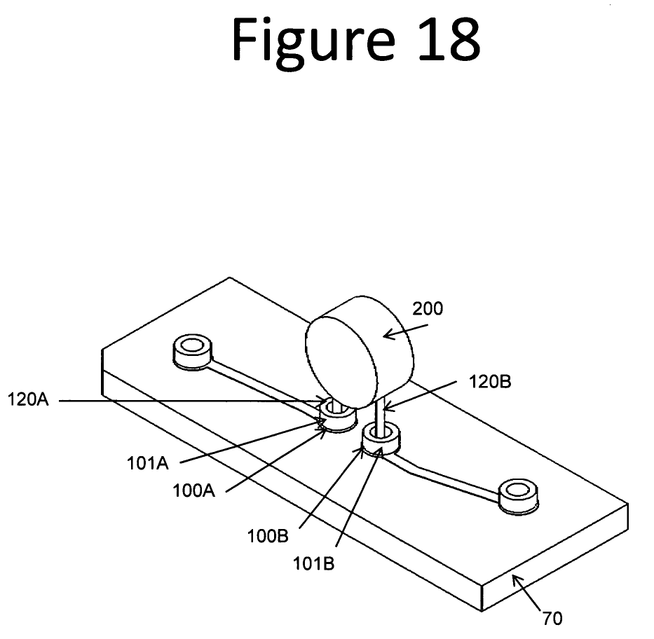

FIG. 18 shows a capacitor, 200, attached to a printed circuit board, 70. Lead, 120A, of capacitor 200 is inserted into lead-receptacle 101A, which is in electrical communication with lead pad 100A which is at one end of trace 80A, which terminates and is in electrical communication wire-receptacle 90A. Likewise, lead 120B of capacitor 200 is inserted into lead-receptacle 101B, which is in electrical communication with lead-pad 100B at one end of trace 80B, which terminates and is in electrical communication with wire-receptacle 90B on printed circuit board 70.

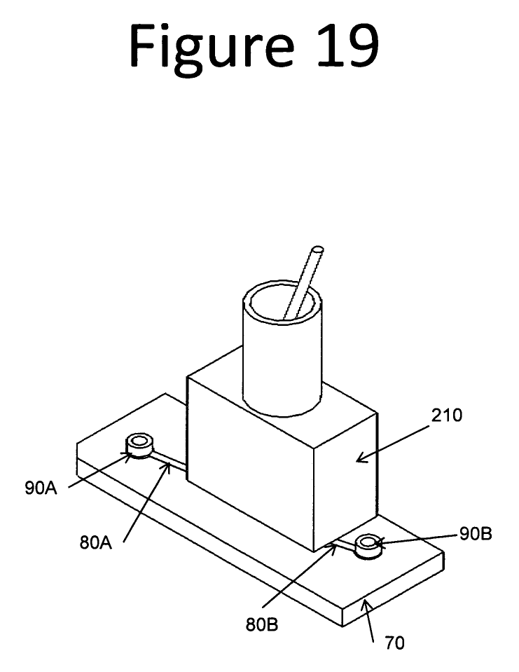

FIG. 19 shows a printed circuit board 70 having an SPST switch, 210 connected onto printed circuit board 70. SPST switch has two leads (not shown) in electrical communication with two lead-pads (not shown). The lead-pad at one end of trace 80A terminates and is electrical communication with wire-receptacle 90A. The second lead-pad is at one end of trace 80B, which terminates and is in electrical communication with wire-receptacle 90B.

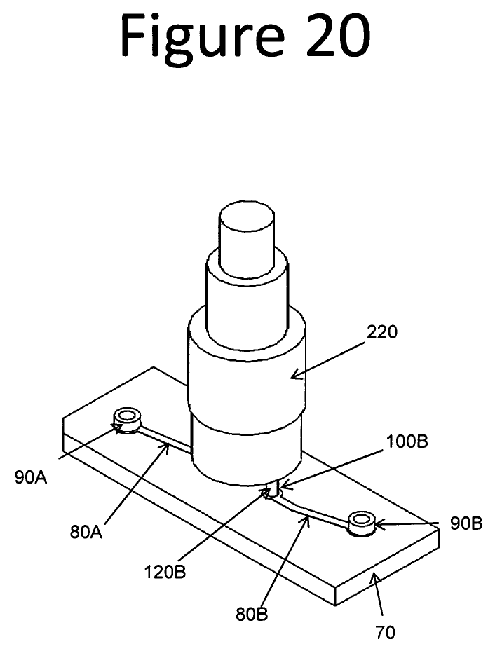

FIG. 20 shows a printed circuit board, 70 having a PB switch, 220, connected onto printed circuit board 70. PB switch 220 has two leads, one lead (not shown) at one end of trace 80A; the other end of trace 80A terminates at and is in electrical communication with wire-receptacle 90A. The second lead 120B is in electrical communication with lead-pad 100B at one end of trace 80B, and the other end of trace 80B terminates at and is in electrical communication with wire-receptacle 90B.

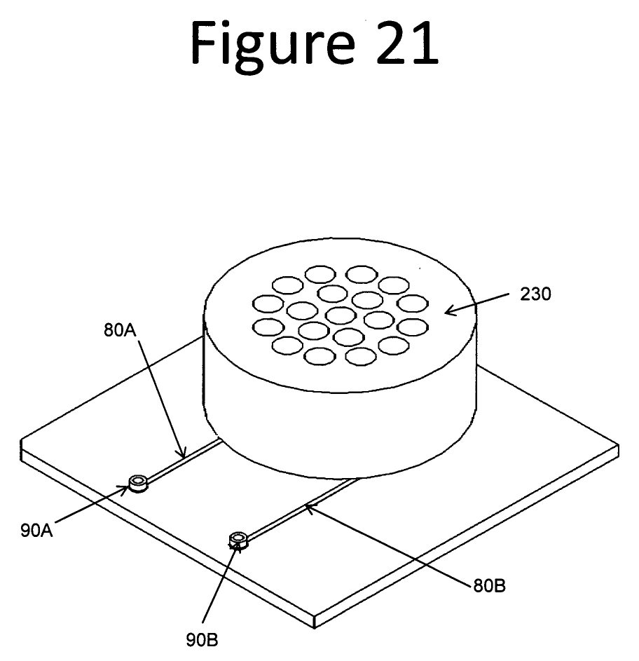

FIG. 21 shows a printed circuit board 70 having a speaker 230 connected onto printed circuit board 70. Speaker 230 has two leads (not shown) in electrical communication with two lead-pads (not shown). The lead-pad at one end of trace 80A terminates and is in electrical communication with wire-receptacle 90A. A second lead-pad is at one end of trace 80B, which terminates and is electrical communication with wire-receptacle 90B.

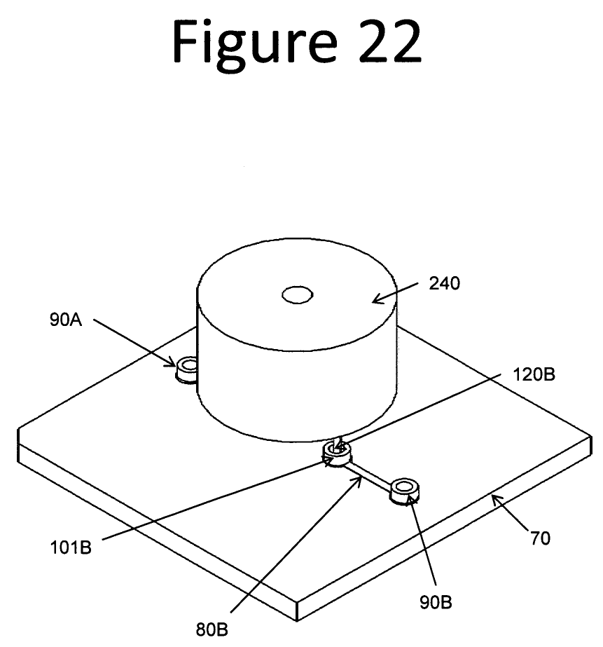

FIG. 22 shows a printed circuit board, 70, having a microphone, 240, connected onto printed circuit board 70. Microphone, 240, has two leads, one lead (not shown) in electrical communication with a lead-pad (not shown) at one end of a first trace (not shown) which terminates and is in electrical communication with wire-receptacle 90A; and a second lead 120B is in electrical communication with lead-receptacle 101B at one end of trace 80B, the other end of trace 80B terminates at and is in electrical communication with wire-receptacle 90B.

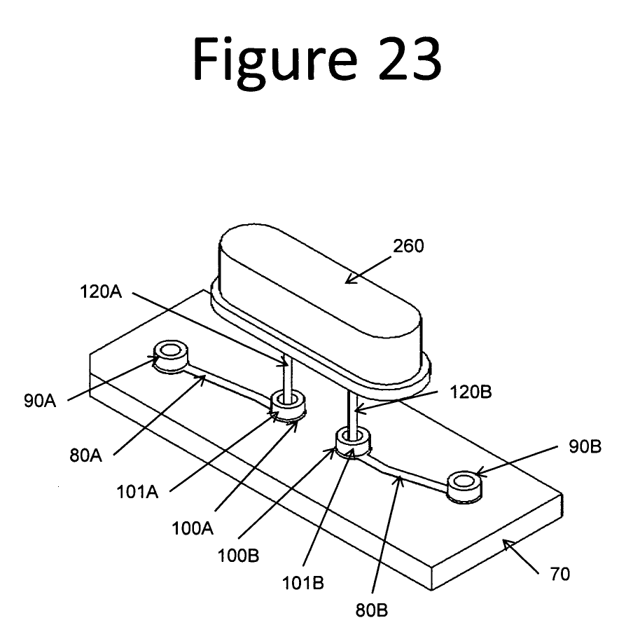

FIG. 23 shows a crystal, 260, attached to a printed circuit board, 70, in which lead 120A of crystal 260, is inserted into lead-receptacle, 101A, which is in electrical communication with lead pad 100A, which is at one end of trace 80A. The other end of trace 80A terminates at and is in electrical communication with wire-receptacle 90A. Likewise, lead 120B, of crystal 260 is inserted into lead-receptacle 101B, which is in electrical communication with lead-pad 101B, of trace 80B on circuit board 70. Trace 80B extends from lead-pad 100B and terminates at and is in electrical communication with wire-receptacle 90B.

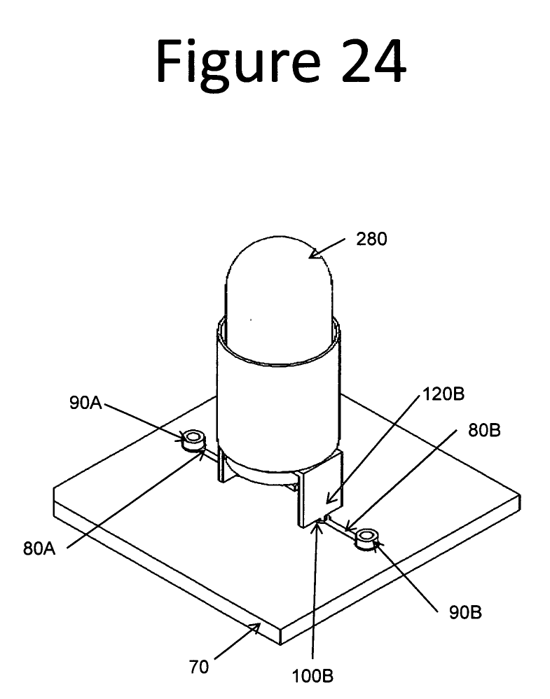

FIG. 24 shows a printed circuit board, 70, having a lamp 280 connected onto printed circuit board 70. Lamp 280 has two leads, one lead (not shown) in electrical communication with a lead-pad (not shown) at one end of a trace 80A which terminates and is in electrical communication with wire-receptacle 90A; and a second lead 120B in electrical communication with lead-pad 100B at one end of trace 80B, the other end of trace 80B terminates at and is in electrical communication with wire-receptacle 90B.

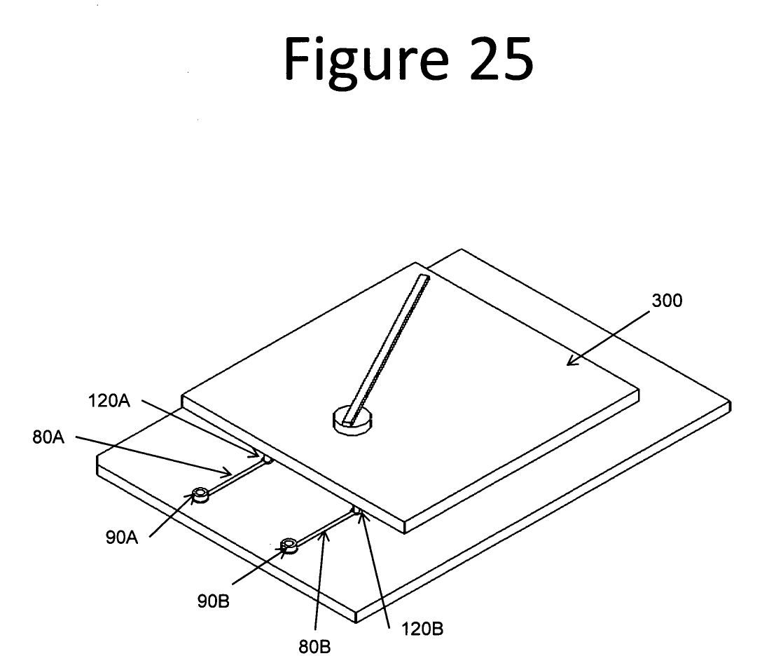

FIG. 25 shows a meter 300 having two leads, 120A and 120B inserted into printed circuit board 70 so that lead 120A is in electrical communication with trace 80A, which extends to an is in electrical communication with wire-receptacle 90A. Lead 120B of meter 300 is attached to and is in electrical communication with one end of trace 80B, which extends to and is in electrical communication with wire-receptacle 90B.

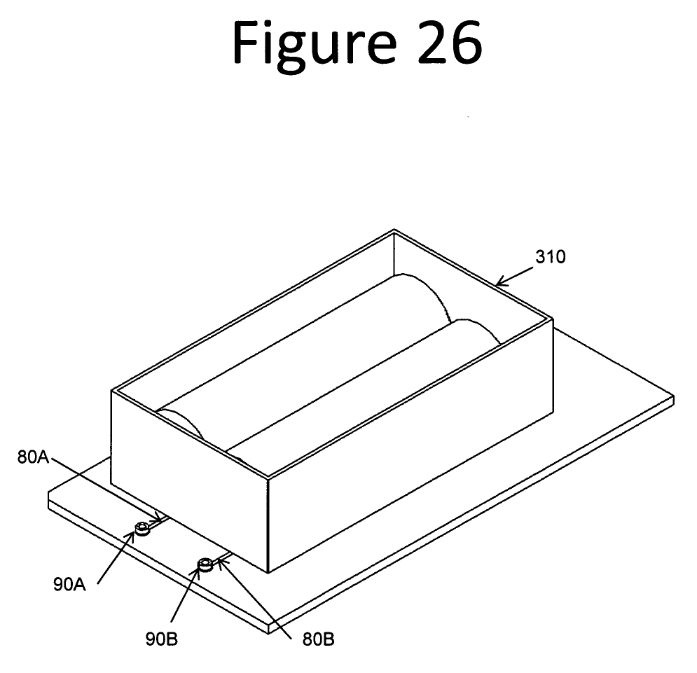

FIG. 26 shows a printed circuit board 70 having a power-supply 310, in this case a battery-holder, attached to printed circuit board 70. Battery-holder 310 has two leads (not shown) in electrical communication with two lead-pads (not shown). One lead-pad is at one end of trace 80A, and the opposite end of trace 80A terminates and is electrical communication with wire-receptacle 90A. The second lead-pad is at one end of trace 80B, and the opposite end of trace 80B terminates at and is in electrical communication with wire-receptacle 90B.

The printed circuit boards of the present invention can also have three traces so that an electronic element having three leads can be attached to a single printed circuit board.

Examples of electronic elements that have three leads include but are not limited to transistors, variable resistors, silicon-controlled rectifiers and SPDT switches.

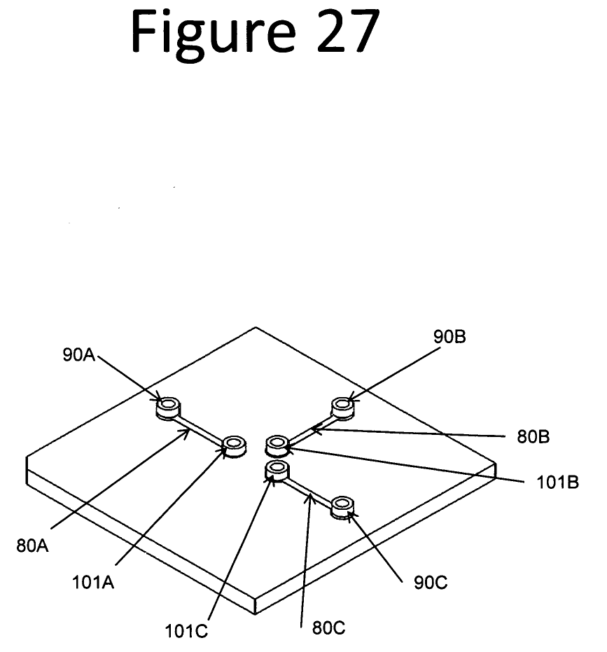

FIG. 27 shows such a printed circuit board 70 having three traces 80A, 80B and 80C. One end, trace 80A terminates at and is in electrical communication with wire-receptacle 90A; the other end of trace 80A terminates at and is in electronic communication with lead-receptacle 101A. One end of trace 80B terminates at and is in electrical communication with wire-receptacle 90B; the other end of trace 80B terminates at and is electrical communication with lead-receptacle 101B. One end of trace 80C terminates at and is in electrical communication with wire-receptacle 90C; the other end of trace 80C terminates at and is in electrical communication with lead-receptacle 101C.

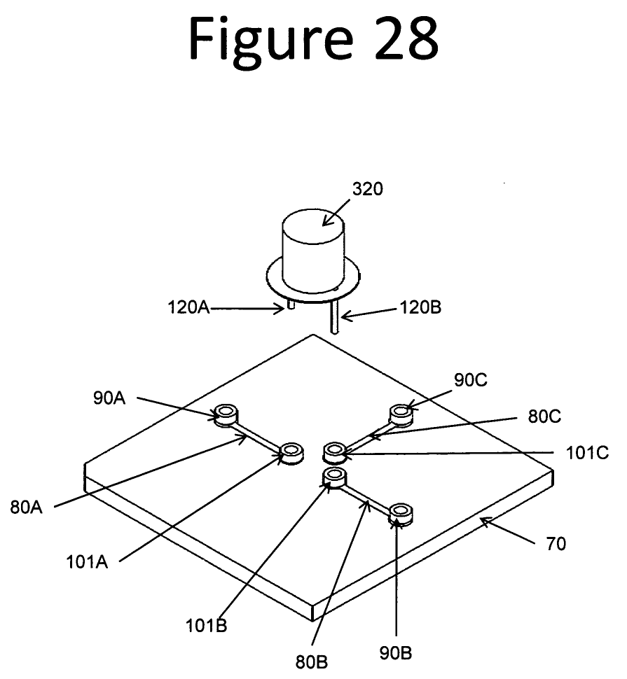

FIG. 28 shows transistor 320 that is positioned to be attached to circuit board 70. Transistor 320 has three leads, lead 120A, lead 120B and lead 120C. Lead 120A is to be inserted into lead-receptacle 101A. Lead-receptacle 101A is attached to and is in electrical communication with one end of trace 80A; and the other end of trace 80A terminates and is in electrical communication with wire-receptacle 90A. Lead 120B is to be inserted into lead-receptacle 101B. Lead-receptacle 101B is attached to and is in electrical communication with one end of trace 80B, and the other end of trace 80B terminates at and is in electrical communication with wire-receptacle 90B. Lead 120C is to be inserted into lead-receptacle 101C. Lead-receptacle 101C is attached to and is in electrical communication with one end of trace 80C, and the other end of trace 80C terminates and is in electrical communication with wire-receptacle 90C.

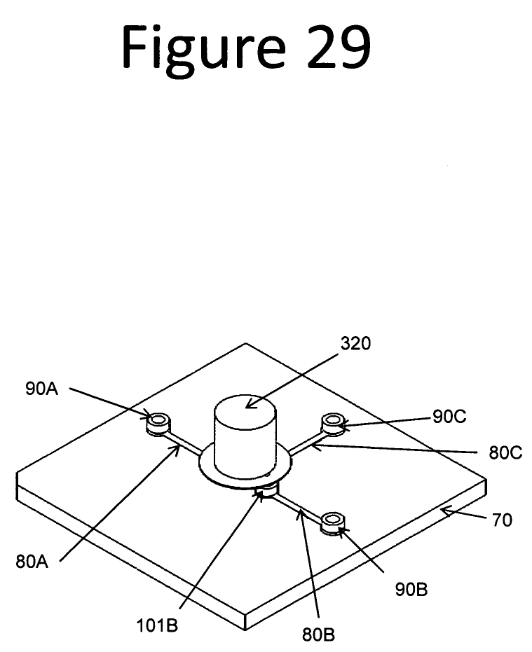

FIG. 29 shows transistor 320 of FIG. 28 attached to printed circuit board 70 as previously described in FIG. 28.

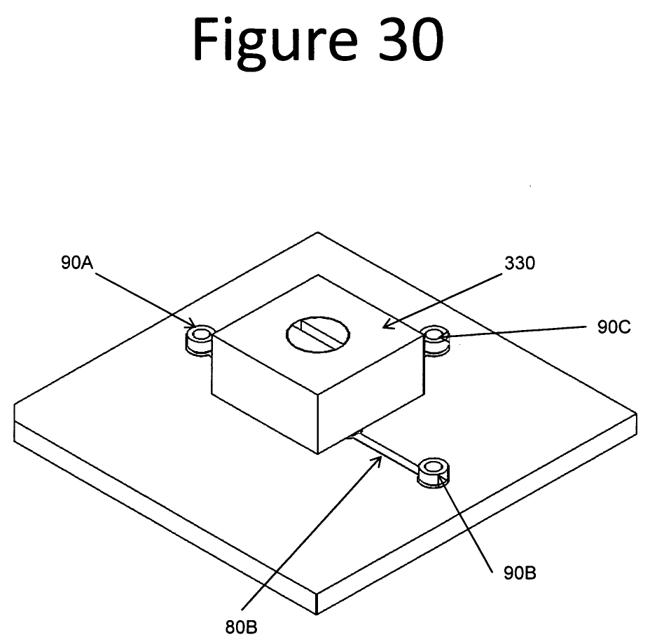

FIG. 30 shows a variable resistor having three leads (not shown) attached to printed circuit board 70. Shown in FIG. 30 are three wire-receptacles, 90A, 90B and 90C. A separate wire can be place into each wire-receptacle enabling the printed circuit board and the variable resistor to be attached to three separate electronic elements each on a different printed circuit board.

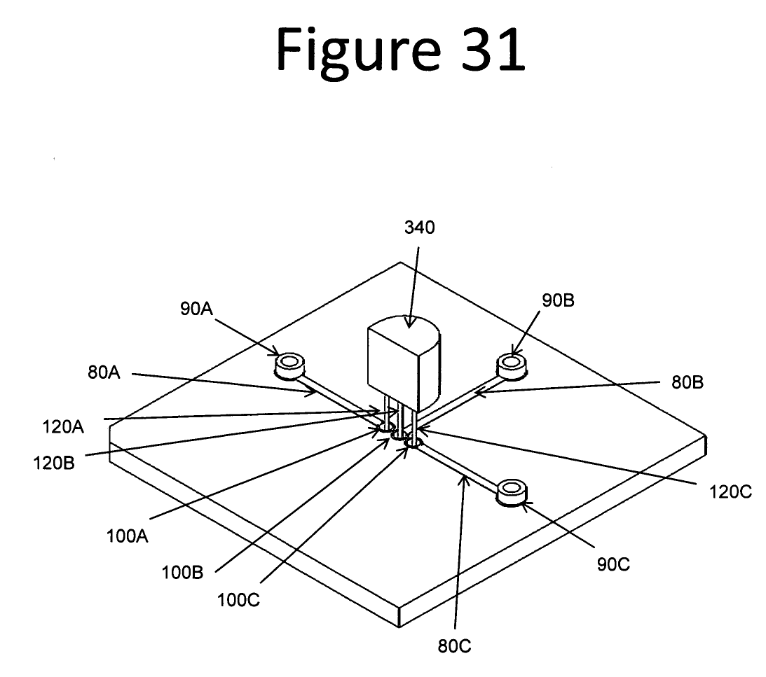

FIG. 31 shows a silicon-controlled rectifier 340 attached to printed circuit board 70. Silicon-controlled rectifier 340 has three leads, lead 120A, lead 120B and lead 120C. Lead 120A is connected to and is in electrical communication with lead-pad 101A, which is at one end of trace 80A; and the other end of trace 80A terminates at and is in electrical communication with wire-receptacle 90A. Lead 120B is connected to and is in electrical communication with lead-pad 100B, which is at one end of trace 80B; the other end of trace 80B terminates at and is in electrical communication with wire-receptacle 90B. Lead 120C is connected to and is in electrical communication with lead-pad 100C, which is at one end of trace 80C; and the other end of trace 80C terminates at and is in electrical communication with wire-receptacle 90C.

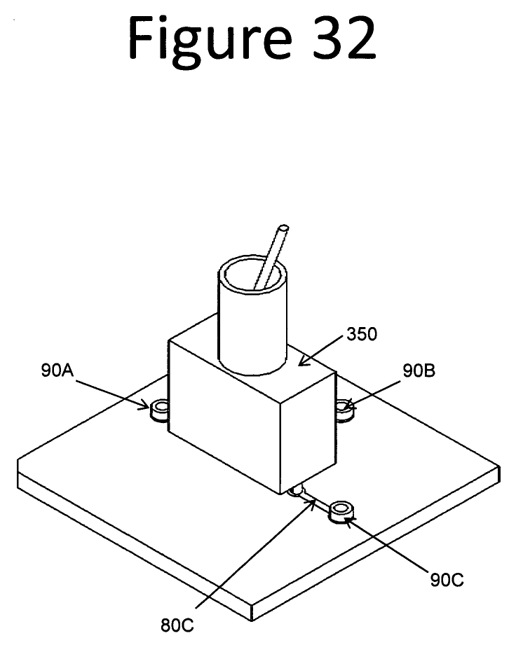

FIG. 32 shows an SPDT switch having three leads (not shown) attached to printed circuit board 70. Each lead is attached to a lead-pad, which is at the end of and is in electrical communication with a trace, the end of the trace opposite the lead-pad terminates at and is in electrical communication with a wire-receptacle. Lead 120C is shown in contact with lead-pad 100C at the end of trace 80C; and the other end of trace 80C terminates and is in electrical communication with wire-receptacle 90C. Wire-receptacles 90A and 90B are shown, but the traces in contact with wire-receptacles 90A and 90B and the lead-pads at each end of the traces, and the other two leads are hidden from view in this drawing.

A single, integrated circuits can also be attached to a single printed circuit board of the present invention. Thus, printed circuit boards onto which only one integrated circuit can be attached are claimed. Examples of such integrated circuits include linear integrated circuits such as amplifiers, operational amplifiers, comparators, inverters, counters, timers, function generators such as sound generators, and voltage regulators; and digital integrated circuits such as logic gates, buffers, inverters, selectors/distributors, encoders/decoders, multiplexers/demultiplexers, counters and timers.

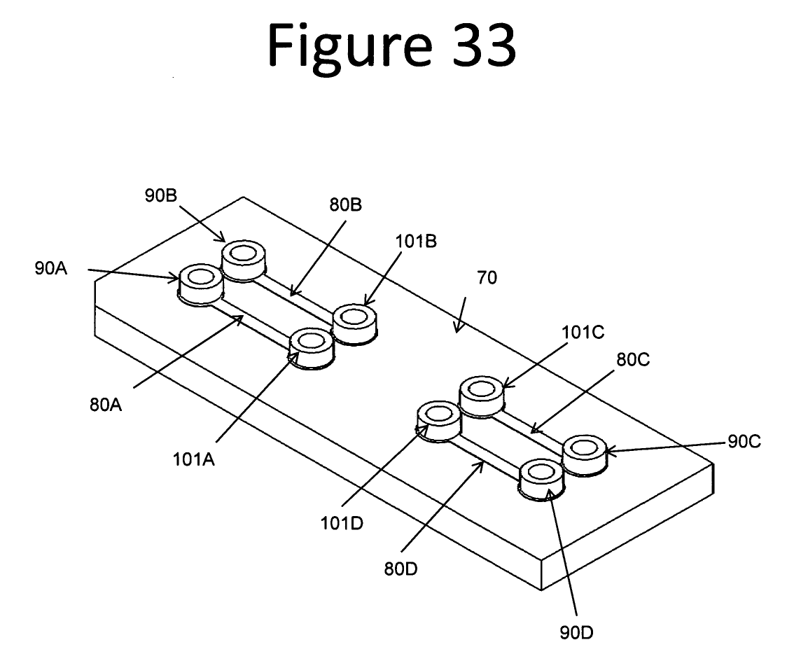

FIG. 33 shows a printed circuit board 70 onto which an integrated circuit having four pins or leads can be attached. Printed circuit board 70 has four traces, 80A, 80B, 80C and 80D. One end of trace 80A is attached to and is in electrical communication with wire-receptacle 90A; the trace extends from wire-receptacle 90A terminates at and is in electrical communication with a lead or pin-receptacle 101A. Trace 80B has a wire-receptacle 90B at one end and a lead or pin receptacle 101B at the other end of the trace each being in electrical communication with the other. Trace 80C has a wire-receptacle 90C at one end and a lead or pin-receptacle 101C at the other end of the trace, each being in electrical communication with the other. Trace 80D has a wire-receptacle 90D at one end and a lead or pin receptacle 101D at the other end of the trace, each being in electrical communication with the other.

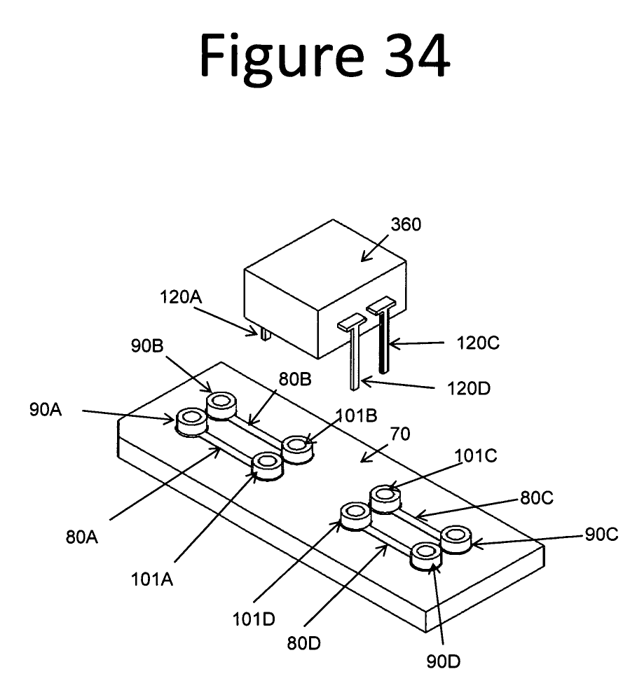

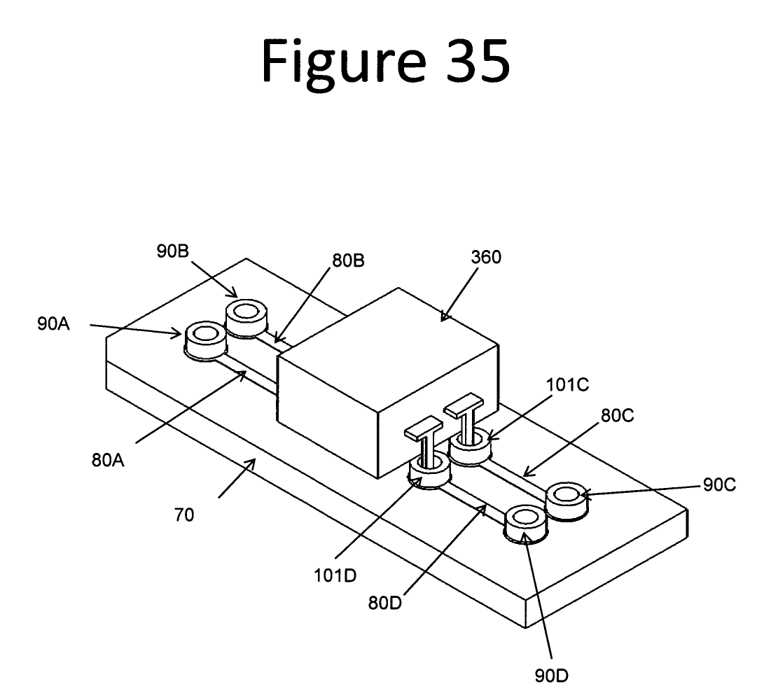

FIG. 34 shows an integrated circuit 360 having 4 dual in-line pins that is to be attached to printed circuit board 70. Lead or pin 120A is to be inserted into lead-receptacle 101A. Lead or pin 120B (not shown) is to be inserted into lead-receptacle 101B. Lead or pin 120C is to be inserted into lead-receptacle 101C. Lead or pin 120D is to be inserted into lead-receptacle 101D. FIG. 35 shows integrated 360 attached to printed circuit board 70.

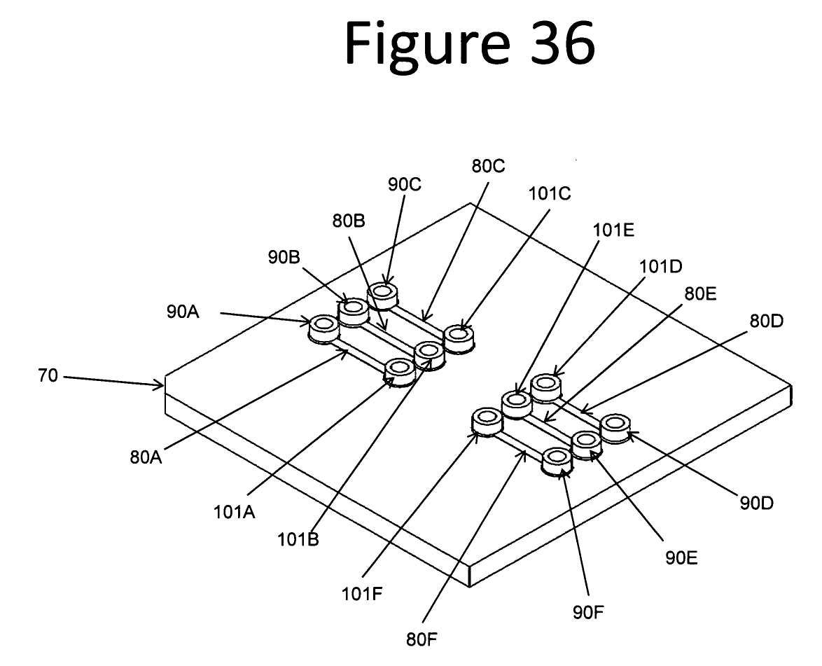

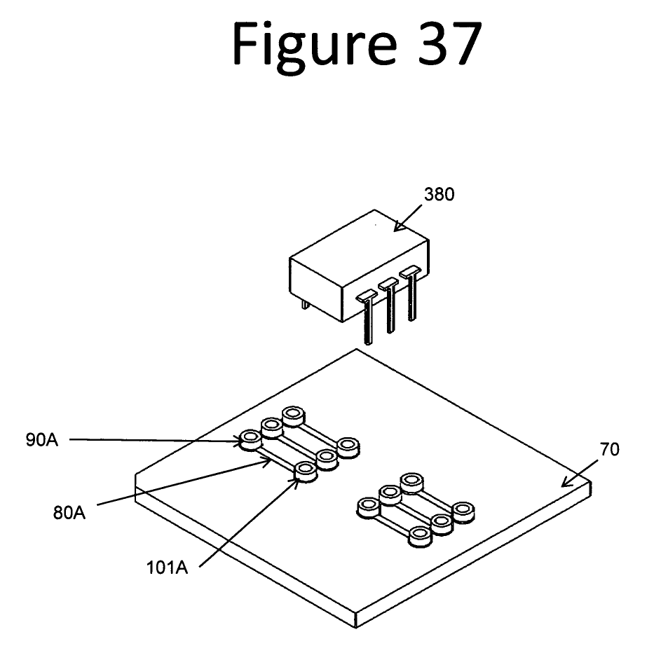

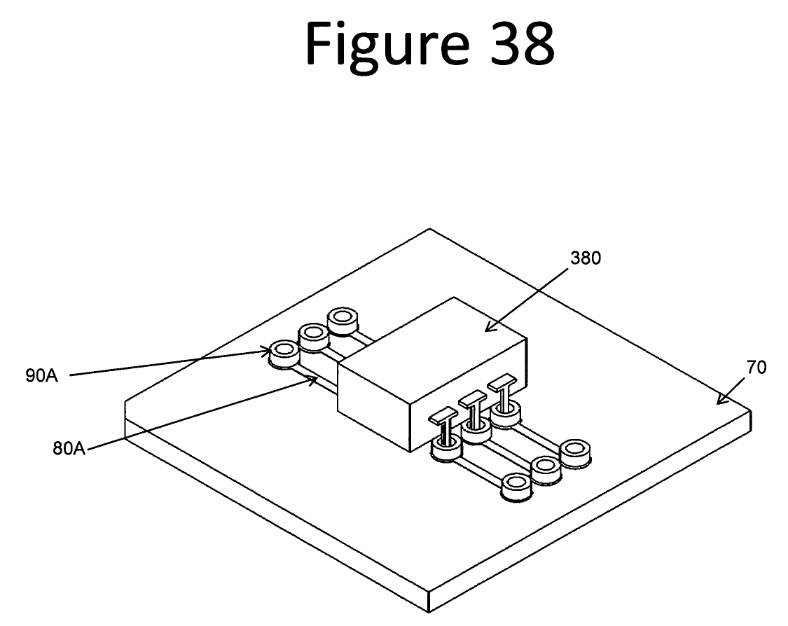

FIG. 36 shows a printed circuit board 70 onto which an integrated circuit having six pins or leads can be attached. Printed circuit board 70 has six traces, 80A, 80B, 80C, 80D, 80E and 80F. Trace 80A has a wire-receptacle 90A at one end and a lead or pin-receptacle 101A at the other end of the trace each being in electrical communication with the other. Trace 80B has a wire-receptacle 90B at one end and a lead or pin receptacle 101B at the other end of the trace each being in electrical communication with the other. Trace 80C has a wire-receptacle 90C at one end and a lead or pin receptacle 101C at the other end of the trace each being in electrical communication with the other. Trace 80D has a wire-receptacle 90D at one end and a lead or pin receptacle 101D at the other end of the trace each being in electrical communication with the other. Trace 80E has a wire-receptacle 90E at one end and a lead or pin receptacle 101E at the other end of the trace each being in electrical communication with the other. Trace 80F has a wire-receptacle 90F at one end and a lead or pin-receptacle 101F at the other end of the trace each being in electrical communication with the other. FIG. 37 shows a six-pin integrated circuit 380 that is to be inserted onto printed circuit board 70 of FIG. 36. FIG. 38 shows integrated circuit 380 of FIG. 37 attached to printed circuit board 70.

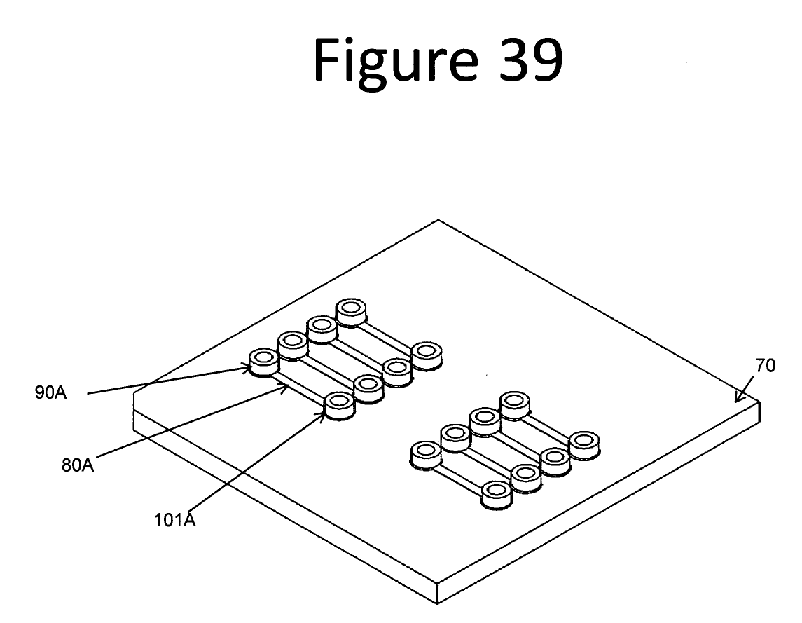

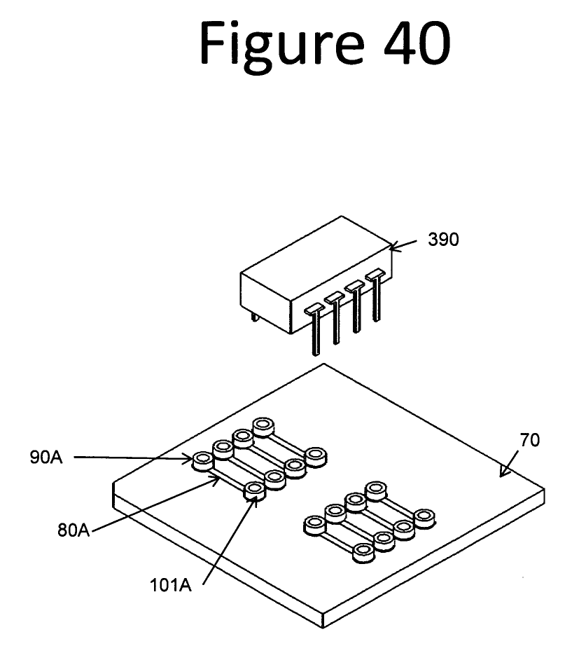

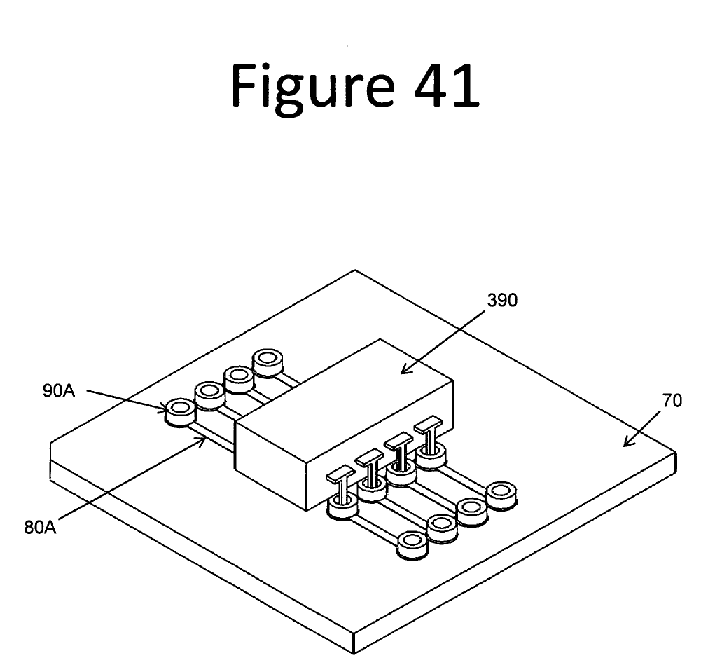

FIG. 39 shows a printed circuit board 70 onto which an integrated circuit having eight pins or leads can be attached. Printed circuit board 70 has eight traces one end of each trace being connected to and in electrical communication with a wire-receptacle and the other end of each trace is connected to and in electrical communication with a lead- or pin-receptacle. This is illustrated by trace 80A, which has a wire-receptacle 90A at one end and a lead or pin receptacle 101A at the other end of the trace each being in electrical communication with the other. FIG. 40 shows an eight-pin integrated circuit 390 that is to be inserted onto printed circuit board 70 of FIG. 39. FIG. 41 shows integrated circuit 390 of FIG. 40 attached to printed circuit board 70.

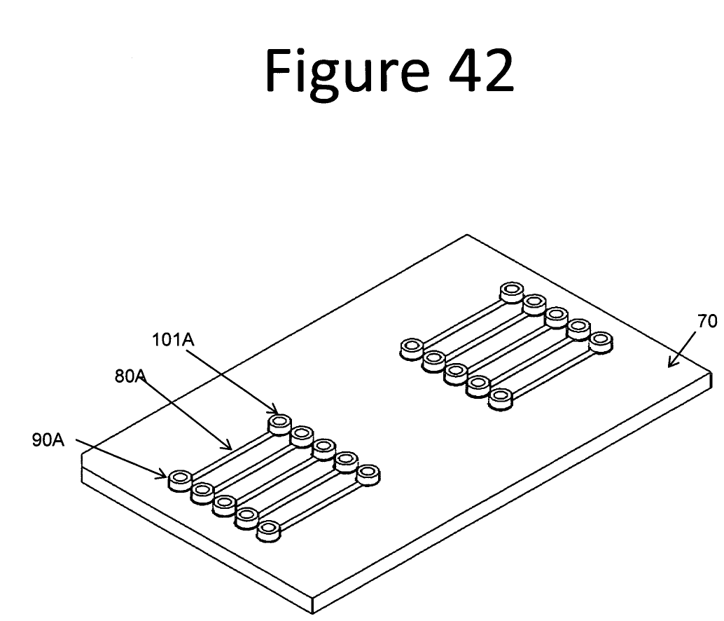

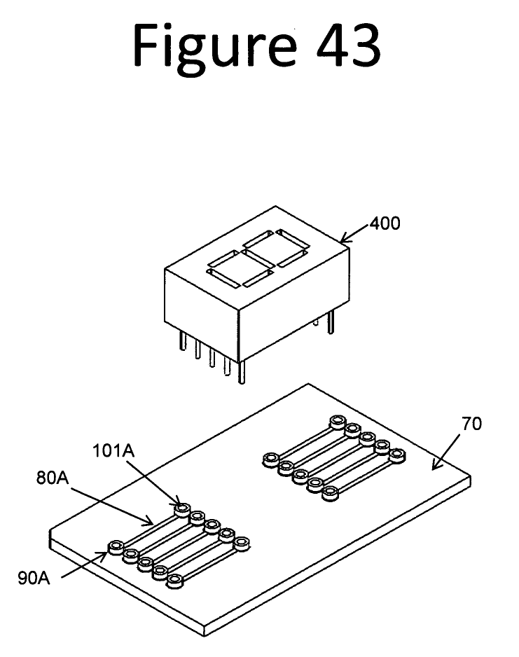

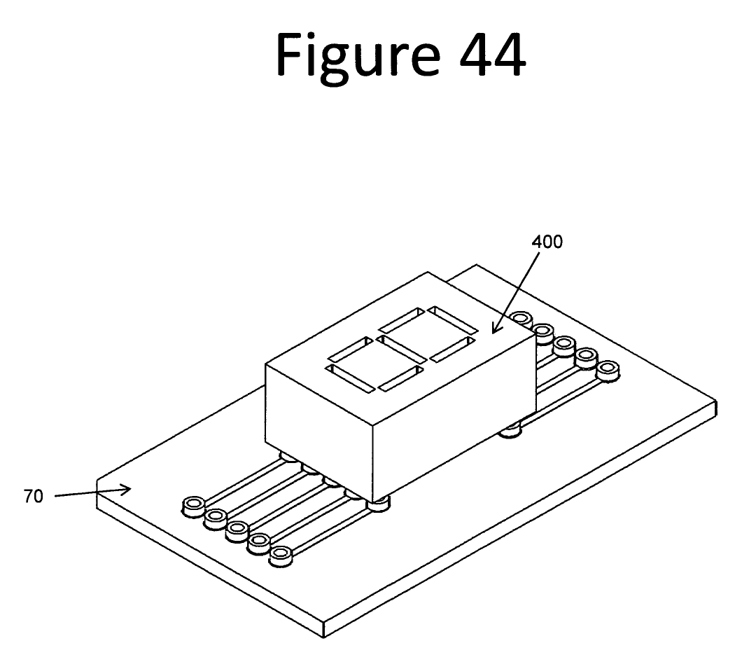

FIG. 42 shows a printed circuit board 70 onto which an integrated circuit having 10 pins or leads can be attached. Printed circuit board 70 has ten traces one end of each trace being connected to and in electrical communication with a wire-receptacle and the other end of each trace is connected to and in electrical communication with a lead- or pin-receptacle. This is illustrated by trace 80A, which has a wire-receptacle 90A at one end and a lead or pin receptacle 101A at the other end of the trace each being in electrical communication with the other. FIG. 43 shows a ten-pin, seven-segment LED 400 that is to be inserted onto printed circuit board 70 of FIG. 42. FIG. 44 shows the ten-pin, seven-segment LED 400 inserted onto printed circuit board 70 of FIG. 42.

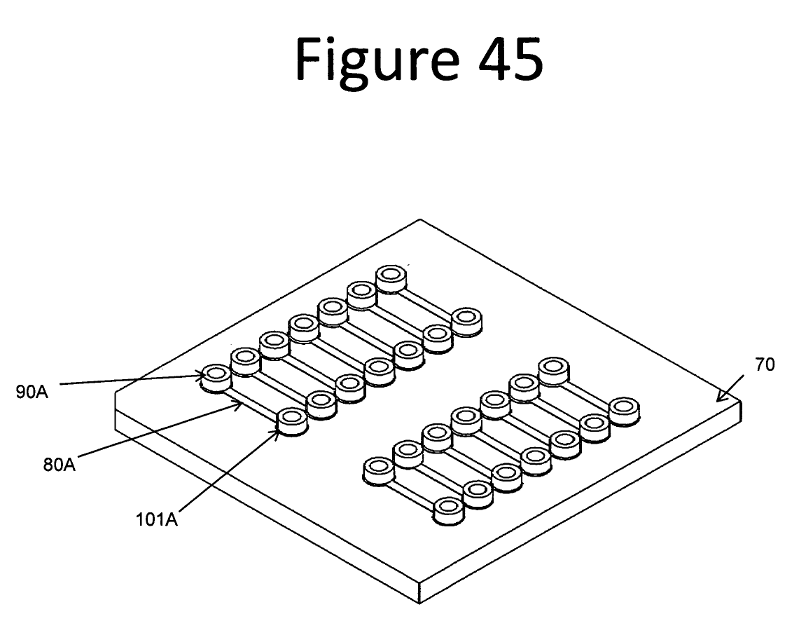

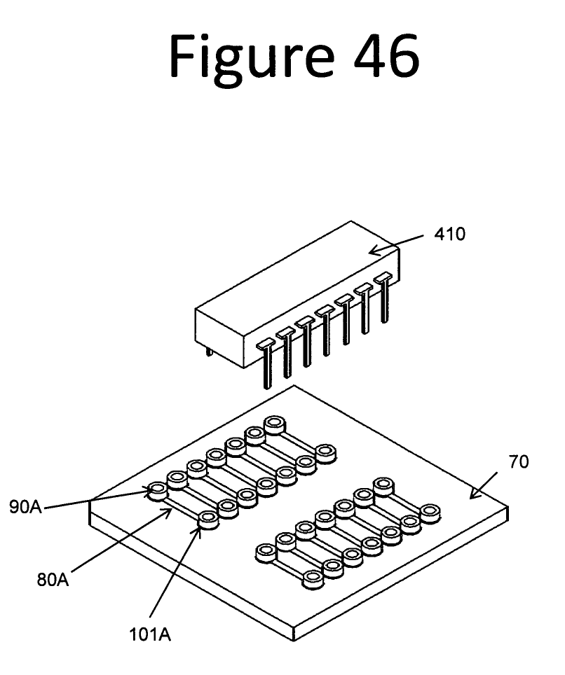

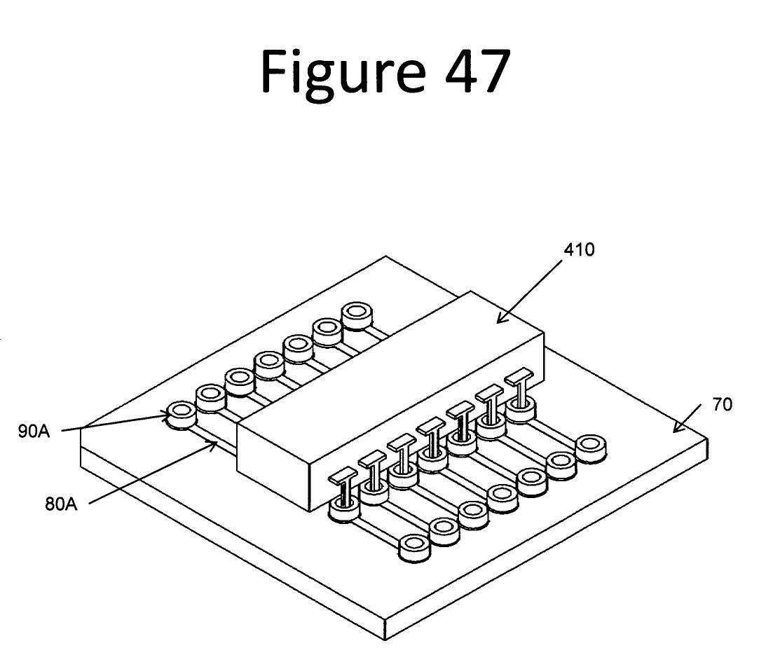

FIG. 45 shows a printed circuit board 70 onto which an integrated circuit having 14 pins or leads can be attached. Printed circuit board 70 has fourteen traces, one end of each trace being connected to and in electrical communication with a wire-receptacle and the other end of which is connected to and in electrical communication with a lead- or pin-receptacle. This is illustrated by trace 80A, which has a wire-receptacle 90A at one end of the trace and a lead- or pin-receptacle 101A at the other end of the trace, each being in electrical communication with the other. FIG. 46 shows a fourteen-pin integrated circuit 410 that is to be inserted onto printed circuit board 70 of FIG. 45. FIG. 47 shows a fourteen-pin integrated circuit 410 inserted onto printed circuit board 70 of FIG. 45.

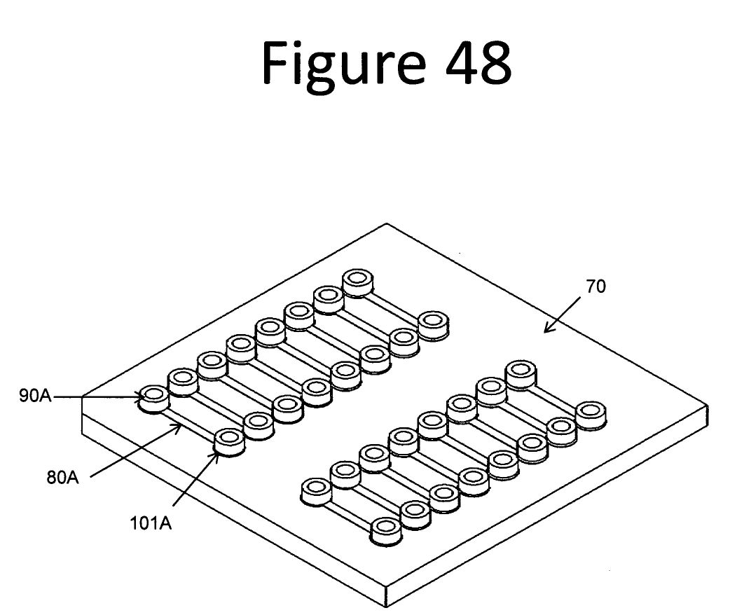

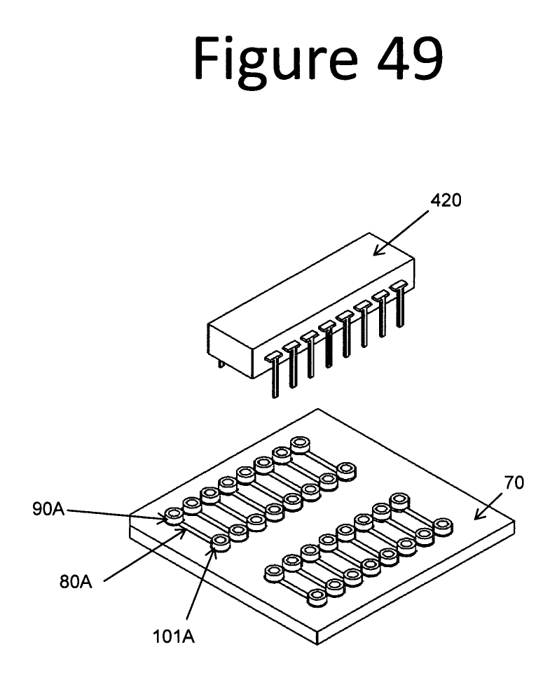

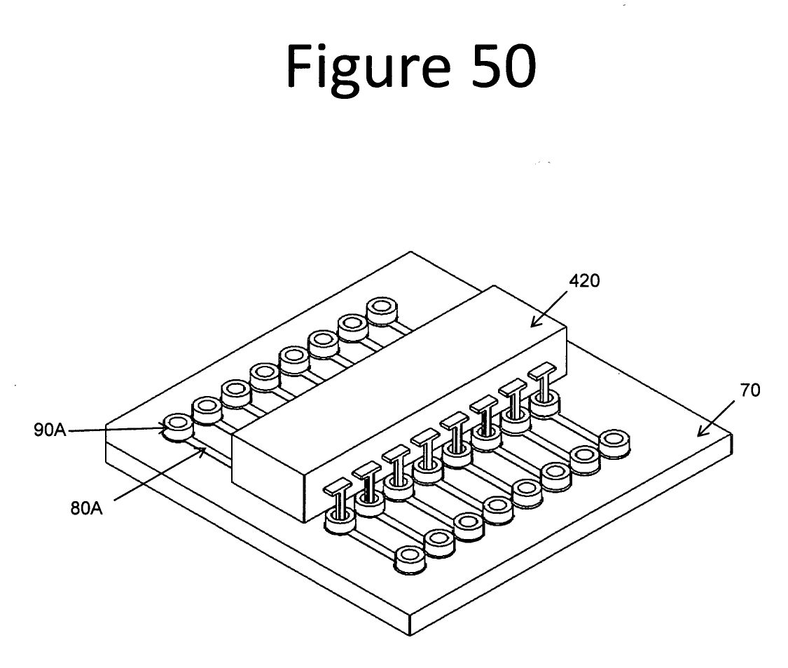

FIG. 48 shows a printed circuit board 70 having sixteen traces onto which an integrated circuit having sixteen leads or pins can be inserted. One end of each trace is connected to and in electrical communication with a wire-receptacle and the other end of the trace is connected to and in electrical communication with a lead- or pin-receptacle. This is illustrated by trace 80A, which has a wire-receptacle 90A at one end of the trace and a lead- or pin-receptacle 101A at the other end of the trace, each being in electrical communication with the other. FIG. 49 shows a sixteen-pin integrated circuit 420 that is to be inserted onto printed circuit board 70 of FIG. 48, wherein each pin is to be inserted into a pin-receptacle at the end of each trace. FIG. 50 shows a sixteen-pin integrated circuit 420 that is inserted onto printed circuit board 70 of FIG. 48.

The preceding discussion is presented to enable a person skilled in the art to make and use the invention. Various modifications to the disclosed embodiments will be readily apparent to those skilled in the art, and the generic principles herein may be applied to other embodiments and applications without departing from the spirit and scope of the present invention. Thus, the present invention is not intended to be limited to the embodiments shown, but is to be accorded the widest scope consistent with the principles and features disclosed herein.

What is claimed is:

1. A printed circuit board having only one circuit element, said circuit element having one or more leads and each lead being in electrical communication to one end of a trace on the printed circuit board, wherein said trace has a second end terminating at a pad, wherein said pad is in electrical communication with a receptacle capable of receiving and retaining a wire.

2. The printed circuit board of claim 1 wherein the circuit element is selected from the group consisting of a 2-lead circuit element, a 3-lead circuit element; a linear integrated circuit, digital integrated circuit

3. The printed circuit board of claim 2 wherein the 2-lead circuit element is selected from the group consisting of resistors, diodes, light emitting diodes (LEDs), capacitors, single pole single throw (SPST) switches, push-button (PB) switches, speakers, microphones, crystals, lamps, meters, battery-holders, photoresistors, photodiodes, phototransistors and solar cells.

4. The printed circuit board of claim 2 wherein the 3-lead circuit element is selected from the group consisting of transistors, variable resistors, silicon controlled rectifiers, and single pole double throw (SPDT) switches.

5. The printed circuit board of claim 2 wherein the linear integrated circuit element is selected from the group consisting of amplifiers, operational amplifiers, comparators, inverters, counters, timers, function generators, and voltage regulators.

6. The printed circuit board of claim 2 wherein the digital integrated circuit element is selected from the group consisting of logic gates, buffers, inverters, selectors/distributors, encoders/decoders, multiplexers/demultiplexers, counters and timers.

7. The printed circuit board of claim 2 wherein the linear integrated circuit element or digital circuit element has 4-64 leads or pins.

8. The printed circuit board of claim 7 wherein the linear integrated circuit element or the digital circuit element has 4, 6, 8, 10, 14 or 16 leads or pins.

9. The printed circuit board of claim 1 wherein said printed circuit board has at least four sides, wherein two sides each have a length ranging from about 0.25 inches to about 7 inches.

10. The printed circuit board of claim 9 wherein said printed circuit board has at least four sides, wherein two sides each have a length selected from the group consisting of 0.4 inches, 1.1 inches, 1.8 inches, 2.5 inches, 3.2 inches, 3.9 inches and 4.9 inches.

11. The printed circuit board of claim 1 wherein said printed circuit board has the same number of traces as the circuit element has leads, and wherein each trace is in electrical communication with a receptacle capable of receiving and retaining a wire.

12. A printed circuit board selected from the group consisting of a printed circuit board having only two traces, a printed circuit board having only three traces, a printed circuit board having only four traces, a printed circuit board having only six traces, a printed circuit board having only eight traces, a printed circuit board having only ten traces, a printed circuit board having only twelve traces, a printed circuit board having only fourteen traces and a printed circuit board having only sixteen traces, wherein each trace has two ends, one end of said trace being in electrical communication with a receptacle capable of receiving and retaining a wire, and the second end of said trace being in electrical communication with a lead-pad.

13. The printed circuit board of claim 12 wherein said printed circuit board has at least four sides, wherein two sides have a length ranging from about 0.3 inches to about 5 inches.

14. The printed circuit board of claim 13 wherein said printed circuit board has at least four sides, wherein two sides have a length selected from the group consisting of 0.4 inches, 1.1 inches, 1.8 inches, 2.5 inches, 3.2 inches, 3.9 inches and 4.9 inches.

15. The printed circuit board of claim 12 wherein the lead-pad is connected to a receptacle capable of receiving and retaining a lead or pin of a circuit element.

16. The printed circuit board of claim 15 wherein said circuit board has at least four sides, wherein two sides have a length ranging from about 0.3 inches to about 5 inches.

17. The printed circuit board of claim 16 wherein said printed circuit board has at least four sides, wherein two sides have a length selected from the group consisting of 0.4 inches, 1.1 inches, 1.8 inches, 2.5 inches, 3.2 inches, 3.9 inches and 4.9 inches.

18. A printed circuit board selected from the group consisting of a printed circuit board having only two traces, a printed circuit board having only three traces, a printed circuit board having only four traces, a printed circuit board having only six traces, a printed circuit board having only eight traces, a printed circuit board having only ten traces, a printed circuit board having only twelve traces, a printed circuit board having only fourteen traces and a printed circuit board having only sixteen traces, wherein each trace has two ends, one end being a receptacle pad connected to a receptacle capable of receiving and retaining a wire, and the second end of said trace being a lead-pad electrically connected to a lead-receptacle, wherein said lead-receptacle is capable of receiving and retaining a lead or pin from a circuit element.

19. The printed circuit board of claim 18 wherein said circuit board has at least four sides, wherein two sides have a length ranging from about 0.25 inches to about 7 inches.

20. The printed circuit board of claim 19 wherein said printed circuit board has at least four sides, wherein two sides have a length selected from the group consisting of 0.4 inches, 1.1 inches, 1.8 inches, 2.5 inches, 3.2 inches, 3.9 inches and 4.9 inches.

21. The printed circuit board of claim 18 wherein said printed circuit board has the same number of traces as the circuit element has leads, and wherein each trace is in electrical communication with a receptacle capable of receiving and retaining a wire.

22. The printed circuit board of claim 18 wherein the circuit elements are selected from the group consisting of a 2-lead circuit element, a 3-lead circuit element, a linear integrated circuit element, and a digital integrated circuit element.

23. The printed circuit board of claim 22 wherein the 3-lead circuit element is selected from the group consisting of transistors, variable resistors, silicon controlled rectifiers, and single pole double throw (SPDT) switches.

24. The printed circuit board of claim 22 wherein the linear integrated circuit element is selected from the group consisting of amplifiers, operational amplifiers, comparators, inverters, counters, timers, function generators, and voltage regulators.

25. The printed circuit board of claim 22 wherein the digital integrated circuit element is selected from the group consisting of logic gates, buffers, inverters, selectors/distributors, encoders/decoders, multiplexers/demultiplexers, counters and timers.

26. The printed circuit board of claim 22 wherein the linear integrated circuit element or digital circuit element has 4-64 leads or pins.

27. The printed circuit board of claim 26 wherein the linear integrated circuit element or the digital circuit element has 4, 6, 8, 10, 14 or 16 leads or pins.
